(19) United States
(12) Patent Application Publication
(10) Pub. No.: US 2025/0048632 A1
(43) Pub. Date: Feb. 6, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Juhyung KIM, Suwon-si (KR); Jisung KIM, Suwon-si (KR); Chaeho KIM, Suwon-si (KR); Youjung KIM, Suwon-si (KR); Kwangmin PARK, Suwon-si (KR)

(73) Assignee: Samsung Electronics Co., Ltd., Suwon-si (KR)

(21) Appl. No.: 18/673,568

(22) Filed: May 24, 2024

(30) Foreign Application Priority Data
Jul. 31, 2023 (KR) 10-2023-0099661

(51) Int. Cl. H10B 43/27; H01L 25/065; H10B 43/10; H10B 43/35; H10B 43/40; H10B 51/10; H10B 51/20; H10B 51/40; H10B 80/00

(52) U.S. Cl. CPC H10B 43/27; H01L 25/0652; H10B 43/10; H10B 43/35; H10B 43/40; H10B 51/10; H10B 51/20; H10B 51/40; H10B 80/00; H01L 2225/06506

(57) ABSTRACT

A semiconductor device may include a stack structure including interlayer insulating layers and gate electrodes alternately stacked in a vertical direction; a vertical pillar in a hole penetrating through the stack structure, the vertical pillar including a channel layer; and protrusions between the vertical pillar and the gate electrodes. The protrusions may be spaced apart from each other in the vertical direction. The protrusions may include a first data storage layer, a second data storage layer between the first data storage layer and the channel layer, and a first conductive layer in contact with a first side surface of the second data storage layer. A material of the second data storage layer may be from a material of the first data storage layer.

### CROSS-REFERENCE TO RELATED APPLICATION(S)

This application claims benefit of priority to Korean Patent Application No. 10-2023-0099661 filed on Jul. 31, 2023 in the Korean Intellectual Property Office, the disclosure of which is incorporated herein by reference in its entirety.

### BACKGROUND

Example embodiments of the present disclosure relate to a semiconductor device, a method of manufacturing the same, and/or a data storage system including the same.

A semiconductor device able to store high-capacity data in a data storage system requiring data storage may be necessary. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure relates to a semiconductor device which may increase a memory window.

An example embodiment of the present disclosure relates to a data storage system including a semiconductor device which may increase a memory window.

An example embodiment of the present disclosure relates to a method of manufacturing a semiconductor device which may increase a memory window.

According to an example embodiment of the present disclosure, a semiconductor device may include a stack structure including interlayer insulating layers and gate electrodes alternately stacked in a vertical direction; a vertical pillar in a hole penetrating through the stack structure, the vertical pillar including a channel layer; and protrusions between the vertical pillar and the gate electrodes, the protrusions spaced apart from each other in the vertical direction. Each of the protrusions may include a first data storage layer, a second data storage layer between the first data storage layer and the channel layer, and a first conductive layer. The second data storage layer may include a first side surface and a second side surface opposing each other. The first conductive layer may be in contact with the first side surface of the second data storage layer. A material of the second data storage layer may be different from a material of the first data storage layer.

According to an example embodiment of the present disclosure, a semiconductor device may include a stack structure including interlayer insulating layers and gate electrodes alternately stacked in a vertical direction; and a vertical structure penetrating through the stack structure, the vertical structure including a vertical pillar disposed in a hole penetrating through the stack structure, the vertical structure including protrusions between the vertical pillar and the gate electrodes, and the vertical pillar including a channel layer. The protrusions may be spaced apart from each other in the vertical direction. The vertical structure may include a first data storage layer and a second data storage layer. Each of the protrusions may include at least one of the first data storage layer and the second data storage layer. Each of the protrusions may further include a first conductive layer in contact with at least one of the first data storage layer and the second data storage layer. A material of the second data storage layer may be different from a material of the first data storage layer.

According to an example embodiment of the present disclosure, a data storage system may include a semiconductor device including an input/output pad; and a controller electrically connected to the semiconductor device through the input/output pad and configured to control the semiconductor device. The semiconductor device may further include a stack structure and a vertical structure penetrating through the stack structure. The stack structure may include interlayer insulating layers and gate electrodes alternately stacked in a vertical direction. The vertical structure may include a vertical pillar in a hole penetrating through the stack structure. The vertical pillar may include a channel layer. The vertical pillar may further include protrusions between the vertical pillar and the gate electrodes. The protrusions may be spaced apart from each other in the vertical direction. The vertical structure may include a first data storage layer and a second data storage layer. Each of the protrusions may include at least one of the first data storage layer and the second data storage layer. Each of the protrusions may further include a first conductive layer in contact with at least one of the first data storage layer and the second data storage layer. A material of the second data storage layer may be different from a material of the first data storage layer.

### BRIEF DESCRIPTION OF DRAWINGS

The above and other aspects, features, and advantages of the present disclosure will be more clearly understood from the following detailed description, taken in combination with the accompanying drawings, in which:

FIGS. 1, 2A, and 2B are diagrams illustrating a semiconductor device according to an example embodiment of the present disclosure;

FIG. 3A is an enlarged cross-sectional diagram illustrating a modified example of a portion of a semiconductor device according to an example embodiment of the present disclosure;

FIG. 3B is an enlarged cross-sectional diagram illustrating a modified example of a portion of a semiconductor device according to an example embodiment of the present disclosure;

FIG. 3C is an enlarged cross-sectional diagram illustrating a modified example of a portion of a semiconductor device according to an example embodiment of the present disclosure;

FIG. 3D is an enlarged cross-sectional diagram illustrating a modified example of a portion of a semiconductor device according to an example embodiment of the present disclosure;

FIG. 3E is an enlarged cross-sectional diagram illustrating a modified example of a portion of a semiconductor device according to an example embodiment of the present disclosure;

FIG. 3F is an enlarged cross-sectional diagram illustrating a modified example of a portion of a semiconductor device according to an example embodiment of the present disclosure;

FIG. 3G is an enlarged cross-sectional diagram illustrating a modified example of a portion of a semiconductor device according to an example embodiment of the present disclosure;

FIG. 4A is an enlarged cross-sectional diagram illustrating a modified example of a portion of a semiconductor device according to an example embodiment of the present disclosure;

FIG. 4B is an enlarged cross-sectional diagram illustrating a modified example of a portion of a semiconductor device according to an example embodiment of the present disclosure;

FIG. 4C is an enlarged cross-sectional diagram illustrating a modified example of a portion of a semiconductor device according to an example embodiment of the present disclosure;

FIG. 4D is an enlarged cross-sectional diagram illustrating a modified example of a portion of a semiconductor device according to an example embodiment of the present disclosure;

FIG. 4E is an enlarged cross-sectional diagram illustrating a modified example of a portion of a semiconductor device according to an example embodiment of the present disclosure;

FIG. 4F is an enlarged cross-sectional diagram illustrating a modified example of a portion of a semiconductor device according to an example embodiment of the present disclosure;

FIG. 4G is an enlarged cross-sectional diagram illustrating a modified example of a portion of a semiconductor device according to an example embodiment of the present disclosure;

FIG. 5 is an enlarged cross-sectional diagram illustrating a modified example of a portion of a semiconductor device according to an example embodiment of the present disclosure;

FIG. 6A is an enlarged cross-sectional diagram illustrating a modified example of a portion of a semiconductor device according to an example embodiment of the present disclosure;

FIG. 6B is an enlarged cross-sectional diagram illustrating a modified example of a portion of a semiconductor device according to an example embodiment of the present disclosure;

FIG. 6C is an enlarged cross-sectional diagram illustrating a modified example of a portion of a semiconductor device according to an example embodiment of the present disclosure;

FIG. 6D is an enlarged cross-sectional diagram illustrating a modified example of a portion of a semiconductor device according to an example embodiment of the present disclosure;

FIG. 6E is an enlarged cross-sectional diagram illustrating a modified example of a portion of a semiconductor device according to an example embodiment of the present disclosure;

FIG. 6F is an enlarged cross-sectional diagram illustrating a modified example of a portion of a semiconductor device according to an example embodiment of the present disclosure;

FIG. 7 is a cross-sectional diagram illustrating a semiconductor device according to an example embodiment of the present disclosure;

FIG. 8 is a cross-sectional diagram illustrating a semiconductor device according to an example embodiment of the present disclosure;

FIG. 9 is a cross-sectional diagram illustrating a semiconductor device according to an example embodiment of the present disclosure;

FIGS. 10 and 11A to 11D are illustrating a method of manufacturing a semiconductor device according to an example embodiment of the present disclosure;

FIGS. 12 and 13A to 15E are illustrating a modified example of a method of manufacturing a semiconductor device according to an example embodiment of the present disclosure;

FIG. 16 is a diagram illustrating a data storage system including a semiconductor device according to an example embodiment of the present disclosure;

FIG. 17 is a perspective diagram illustrating a data storage system including a semiconductor device according to an example embodiment of the present disclosure; and

FIG. 18 is a cross-sectional diagram illustrating a semiconductor package according to an example embodiment of the present disclosure.

### DETAILED DESCRIPTION

Hereinafter, embodiments of the present disclosure will be described as follows with reference to the accompanying drawings. Hereinafter, terms such as “upper portion,” “middle portion,” and “lower portion” may be replaced with other terms, for example, “first,” “second,” and “third” to describe elements of the specification. Terms such as “first,” “second,” and “third” may be used to describe different elements, but the elements are not limited by the terms, and a “first element” may be referred to as a “second element.”

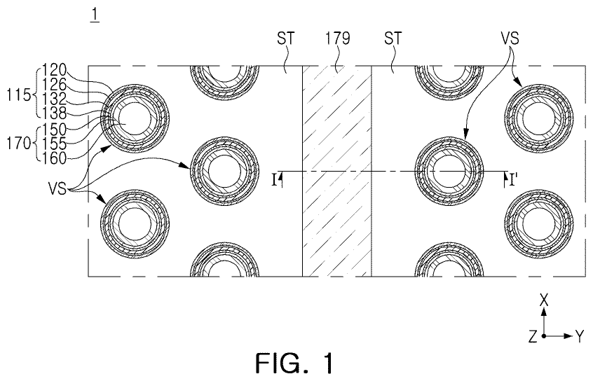

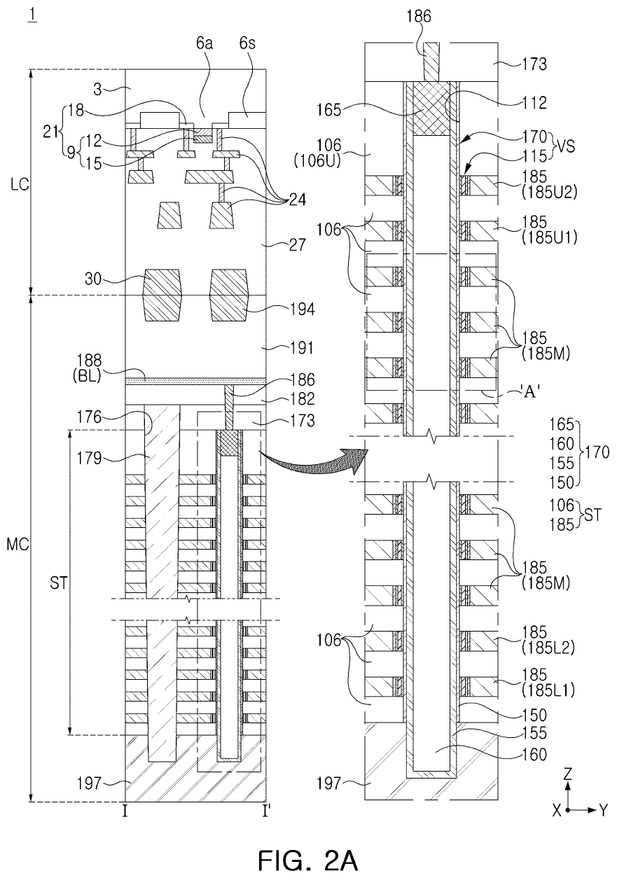

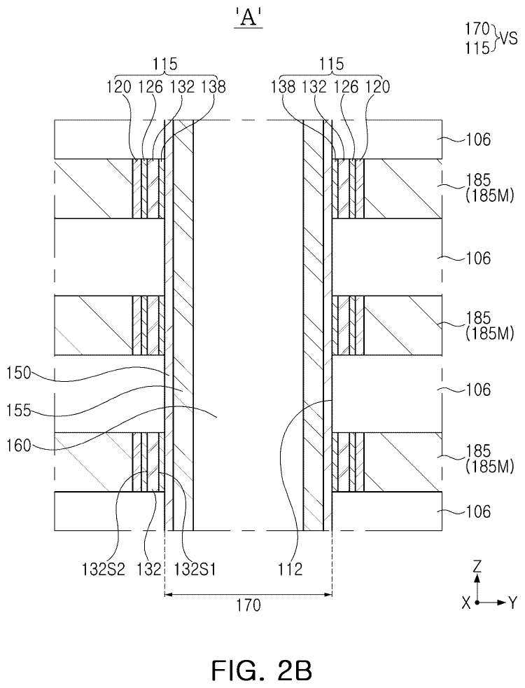

A semiconductor device according to an example embodiment will be described with reference to FIGS. 1, 2A and 2B. FIG. 1 is a diagram illustrating a semiconductor device according to an example embodiment, viewed from the above, FIG. 2A is a cross-sectional diagram illustrating a region taken along line I-I′ in FIG. 1, and FIG. 2B is an enlarged cross-sectional diagram illustrating region “A” in FIG. 2A.

Referring to FIGS. 1, 2A and 2B, a semiconductor device 1 according to an example embodiment may include a first region MC and a second region LC. The first region MC may vertically overlap the second region LC.

In an example embodiment, in the first region MC, three-dimensionally arranged memory cells may be disposed, and the second region LC may be configured as a peripheral circuit region.

In an example embodiment, the first region MC may be referred to as a memory chip structure or a first chip structure, and the second region LC may be referred to as a peripheral circuit structure or a second chip structure.

The first region MC may include a stack structure ST and a vertical structure VS penetrating through the stack structure ST. The stack structure ST may include interlayer insulating layers 106 and gate electrodes 185 alternately stacked in the vertical direction Z. The stack structure ST may vertically overlap the second region LC, which may be configured as a peripheral circuit structure.

The gate electrodes 185 may include lower gate electrodes 185L1 and 185L2, intermediate gate electrodes 185M, and upper gate electrodes 185U1 and 185U2. The lower gate electrodes 185L1 and 185L2 may include a first lower gate electrode 185L1 and a second lower gate electrode 185L2 stacked in order. The upper gate electrodes 185U1 and 185U2 may include a first upper gate electrode 185U1 and a second upper gate electrode 185U2 stacked in order.

The intermediate gate electrodes 185M may form wordlines. The intermediate gate electrodes 185M may also be referred to as wordlines.

In an example, at least one of the lower gate electrodes 185L1 and 185L2 may be configured as a lower select gate electrode, and at least one of the upper gate electrodes 185U1 and 185U2 may be configured as an upper select gate electrode. For example, at least one of the lower gate electrodes 185L1 and 185L2 may be configured as a ground select gate electrode, and at least one of the upper gate electrodes 185U1 and 185U2 may be configured as a string select gate electrode.

In an example, at least one of the lower gate electrodes 185L1, 185L2 and the upper gate electrodes 185U1, 185U2 may be configured as an erase control gate electrode can be used for an erase operation by generating a GIDL current due to gate induced drain leakage (GIDL) phenomenon in a NAND flash memory device. For example, the first lower gate electrode 185L1 may be configured as a lower erase control gate electrode, the second lower gate electrode 185L2 may be configured as a lower select gate electrode, the first upper gate electrode 185U1 may be configured as an upper select gate electrode, and the second upper gate electrode 185U2 may be configured as an upper erase control gate electrode.

The interlayer insulating layers 106 may include an insulating material such as silicon oxide. Among the interlayer insulating layers 106, the uppermost interlayer insulating layer 106U may be greater than the remaining interlayer insulating layers.

The gate electrodes 185 may include a conductive material. For example, each of the gate electrodes 185 may be polysilicon, W, Ru, Mo, Nb, Ni, Co, Ti, Ta, TiN, TaN, WN, NbN, TiAl, TiAIN, TiSi, TiSiN, TaSi, TaSiN, or may be formed of RuTiN, NiSi, CoSi, or a combination thereof, but an example embodiment thereof is not limited thereto. For example, each of the gate electrodes 185 may include a single layer or multiple layers of the materials mentioned above.

The vertical structure VS may include a vertical pillar 170 disposed in the hole 112 penetrating through the stack structure ST and protrusions 115 disposed between the vertical pillar 170 and the gate electrodes 185.

The vertical pillar 170 may include a channel layer 155. The channel layer 155 may include a semiconductor material. For example, the channel layer 155 may include at least one of doped silicon, undoped silicon, doped polysilicon, undoped polysilicon, or an oxide semiconductor. The oxide semiconductor may be indium gallium zinc oxide (IGZO), but an example embodiment thereof is not limited thereto. For example, the oxide semiconductors may include at least one of indium tungsten oxide (ITO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The vertical pillar 170 may further include an insulating core region 160 and a pad pattern 165 on the insulating core region 160. The channel layer 155 may include a portion disposed on a side surface of the insulating core region 160. The channel layer 155 may further include a portion covering a lower surface of the insulating core region 160. The pad pattern 165 may be connected to the channel layer 155. The pad pattern 165 may be disposed on a level higher than a level of the uppermost second upper gate electrode 185U2 among the gate electrodes 185. The pad pattern 165 may include a conductive material, for example, doped polysilicon with N-type conductivity. The insulating core region 160 may include an insulating material such as silicon oxide.

The vertical pillar 170 may further include an interfacial insulating layer 150 on an external side surface of the channel layer 155. The interfacial insulating layer 150 may include at least one of silicon oxide, SiON, AION, and high-K dielectric. The high-K dielectric may have a dielectric constant higher than that of silicon oxide.

Each of the protrusions 115 may include a first data storage layer 120 and a second data storage layer 132.

The second data storage layer 132 may be disposed between the first data storage layer 120 and the channel layer 155. The second data storage layer 132 may have a first side surface 132S1 and a second side surface 132S2 opposing each other. The first side surface 132S1 may oppose the channel layer 155, and the second side surface 132S2 may oppose the first data storage layer 120.

The material of the first data storage layer 120 may be different from the material of the second data storage layer 132.

The first data storage layer 120 may include a charge trap layer. For example, the first data storage layer 120 may be configured as a charge trap layer which may store data using a charge trap. The first data storage layer 120 may include at least one of SiO, SiN, SiON, SiO/SiN, SiO/SION, SiO/AIO, SiO/HfO, SiO/SiN/SiO or SiO/nano-crystal which may store data using a charge trap. Here, the terms such as SiO/SiN may refer to a stack structure of a SiN material layer and a SiO material layer. The first data storage layer 120 may include at least one of Si (O) N, (Hf, Zr, Al, C, N, Gd, Y, Ti, La, Ta)-doped Si (O) N, or HfO₂.

The second data storage layer 132 may include a ferroelectric layer. For example, the second data storage layer 132, which may be configured as a ferroelectric layer, may have polarization properties depending on the electric field and may have remnant polarization due to a dipole even in the absence of an external electric field. The second data storage layer 132 may record data using a polarization state in the ferroelectric layer. The second data storage layer 132 opposing the intermediate gate electrodes 185M, which may be wordlines, may be regions storing data using polarization states.

The second data storage layer 132 may be configured as a ferroelectric layer including an Hf-based compound, a Zr-based compound, and/or an Hf—Zr-based compound. For example, the Hf-based compound may include a HfO-based ferroelectric material, the Zr-based compound may include a ZrO-based ferroelectric material, and the Hf—Zr based compound may include a ferroelectric material based on hafnium zirconium oxide (HZO).

The second data storage layer 132 may include a ferroelectric material doped with at least one of impurities, for example, Zr, C, Si, Mg, Al, Y, N, Ge, Sn, Gd, La, Sc, and Sr. For example, the ferroelectric layer of the second data storage layer 132 may be at least one of HfO₂, ZrO₂ and HZO doped with at least one of Zr, C, Si, Mg, Al, Y, N, Ge, Sn, Gd, La, Sc and Sr. For example, the ferroelectric layer of the second data storage layer 132 may include Hf₁₋ₓZrₓO₂ (0≤x≤1), (Al, C, N, Gd, Y, Ta, La, Si)-doped HfO₂, or Al₁₋ₓScₓN (0≤x≤1).

The ferroelectric layer of the second data storage layer 132 is not limited to the above-mentioned materials and may include a material having ferroelectric properties for storing data. For example, the ferroelectric layer of the second data storage layer 132 may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF_{0.5}Zr_{0.5}O₂, PbZrₓTi1-xO₃ (0<x<1), Ba(Sr, Ti) O₃, Bi₄₋ₓLaₓTi3O12 (0<x<1), SrBi₂Ta₂O₉, Pb₅Ge₅O₉, SrBi₂Nb₂O₉, and YMnO₃.

The second data storage layer 132 may be configured as a single layer or multiple layers of the ferroelectric materials mentioned above.

Each of the protrusions 115 may further include a conductive layer in contact with at least one side surface of the first and second side surfaces 132S1 and 132S2 of the second data storage layer 132. For example, each of the protrusions 115 may include a first conductive layer 138 in contact with the first side surface 132S1 and a second conductive layer 126 in contact with the second side surface 132S2.

The first conductive layer 138 may be disposed between the second data storage layer 132 and the channel layer 155. The first conductive layer 138 may be disposed between the second data storage layer 132 and the interfacial insulating layer 150. The first conductive layer 138 may be in contact with the interfacial insulating layer 150.

The second conductive layer 126 may be disposed between the first data storage layer 120 and the second data storage layer 132. The second conductive layer 126 may be in contact with the first and second data storage layers 120 and 132.

Each of the first and second conductive layers 138 and 126 may include at least one of a barrier material, a refractory metal, and conductive silicon. The barrier material may be TiN, TaN, or WN, and the refractory metal may be W, Mo, or Nb. The materials of the first and second conductive layers 138 and 126 are not limited to the materials mentioned above. For example, each of the first and second conductive layers 138 and 126 may include Pt, Ru, RuOx, HfN, or ZrN. Each of the first and second conductive layers 138 and 126 may be configured as a single layer or multiple layers of the materials mentioned above.

In an example, the first conductive layer 138 and the second conductive layer 126 may be formed of the same material.

In another example, the first conductive layer 138 and the second conductive layer 126 may be formed of different materials.

The thickness of the second data storage layer 138 may be greater than the thickness of the first data storage layer 120. In example embodiments, the thickness of each component included in the protrusions 115 may refer to a thickness in a vertical direction perpendicular to the vertical direction Z.

The thickness of the first data storage layer 120 may be equal to or greater than about 3 Å, and may be equal to or less than about 50 Å.

The thickness of the second data storage layer 138 may be equal to or greater than about 10 Å, and may be equal to or less than about 130 Å.

The thickness of the first conductive layer 138 may be equal to or greater than about 3 Å, and may be equal to or less than about 50 Å.

The thickness of the second conductive layer 126 may be greater than or equal to about 3 Å, and may be equal to or less than about 50 Å.

Each of the protrusions 115 may be ring-shaped.

The first region MC may further include lower pattern 197 below the stack structure ST. The lower pattern 197 may be in contact with the lowermost interlayer insulating layer among the interlayer insulating layers 106 of the stack structure ST. The lower pattern 197 may include at least one conductive material. For example, the lower pattern 197 may include at least one of a doped polysilicon layer and a metal layer. The lower pattern 197 may also be referred to as a plate pattern or a substrate.

The vertical pillar 170 may extend from the portion penetrating through the stack structure ST into the lower pattern 197 and may be in contact with the lower pattern 197. The lower pattern 197 may be configured as a common source. The channel layer 155 of the vertical pillar 170 may be in contact with the lower pattern 197.

The first region MC further may include a first upper insulating layer 173 on the stack structure ST and the vertical structure VS, and a separation structure 179 disposed in the separation trench 176 penetrating through the first upper insulating layer 173 and the stack structure ST. The separation structure 179 may extend in the first direction X perpendicular to the vertical direction Z, and may isolate the stack structure ST in the second direction Y perpendicular to the first direction X.

The vertical direction Z may be perpendicular to an upper surface of the lower pattern 197, and the first and second directions X and Y may be parallel to the upper surface of the lower pattern 197.

The first region MC may further include a second upper insulating layer 182 on the first upper insulating layer 173.

The first region MC may further include a contact plug 186 penetrating through the first and second upper insulating layers 173 and 182 and electrically connected to the pad pattern 165 of the vertical structure VS, and a conductive line 188 electrically connected to the contact plug 186 on the second upper insulating layer 182. The conductive line 188 may be configured as a bitline (BL). The conductive line 188 may have a line shape extending in the second direction Y.

The first region MC may further include a third upper insulating layer 191 on the second upper insulating layer 182 and the conductive line 188, and first bonding pads 194 having an upper surface coplanar with an upper surface of the third upper insulating layer 191 and having a side surface surrounded by the third upper insulating layer 191.

The second region LC may include a substrate 3, a device isolation region 6s defining an active region 6a below the substrate 3, a peripheral circuit 21 below the substrate 3, a circuit interconnection structure 24 below the peripheral circuit 21, a peripheral insulating structure 27 covering the peripheral circuit 21 and the circuit interconnection structure 24 below the substrate 3, and a second bonding pads 30 having a side surface surrounded by the peripheral insulating structure 27 and a lower surface coplanar with a lower surface of the peripheral insulating structure 27.

The peripheral circuit 21 may include a transistor including a peripheral gate 9 below the active region 6a, and peripheral source/drain regions 18 disposed in the active region 6a on both sides of the peripheral gate 9. The peripheral gate 9 may include a peripheral gate dielectric layer 12 and a peripheral gate electrode 15 below the peripheral gate dielectric layer 12.

The first bonding pads 194 and the second bonding pads 30 may include metal materials and may be bonded to each other. For example, the first bonding pads 194 and the second bonding pads 30 may include copper (Cu), and copper of the first bonding pads 194 and copper of the second bonding pads 30 may be in contact with and bonded to each other. Accordingly, the second region LC may be connected to the first region MC on the first region MC.

In an example embodiment, the first region MC may be referred to as a lower chip structure or a memory structure, and the second region LC may be referred to as an upper chip structure or a peripheral circuit structure.

In an example embodiment, the vertical structure VS may include the vertical pillar 170 and the protrusions 115, and the vertical structure VS may include the first data storage layer 120 and the second data storage layer 132, each of the protrusions 115 may include at least one of the first data storage layer 120 and the second data storage layer 132, and each of the protrusions 115 may include a conductive layer 126 in contact with at least one of the first and second data storage layers 120 and 132.

The semiconductor device 1 according to example embodiments may include the first data storage layer 120 for storing data using a charge trap, and the second data storage layer 132 for storing data using a polarization state. As such, in the memory cell transistor including the first data storage layer 120 and the second data storage layer 132 which may store data in different manners, a difference between a threshold voltage of the memory cell transistor in a programmed state and a threshold voltage of the memory cell transistor in an erased state may be relatively large. As the difference in threshold voltages between the programmed state and the erased state is relatively large, a memory window may be increased.

In example embodiments, free charges of the first and second conductive layers 126 and 138 in contact with the second data storage layer 132 may compensate for polarized charges of the second data storage layer 132, which may be formed of a ferroelectric material. Accordingly, as the first and second conductive layers 126 and 138 in contact with the second data storage layer 132 may reduce depolarization of the second data storage layer 132, the memory window may be limited and/or prevented from being reduced by depolarization of the second data storage layer 132.

In example embodiments, the protrusions 115 may be spaced apart from each other in the vertical direction Z, thereby improving reliability, endurance and retention properties of the semiconductor device 1.

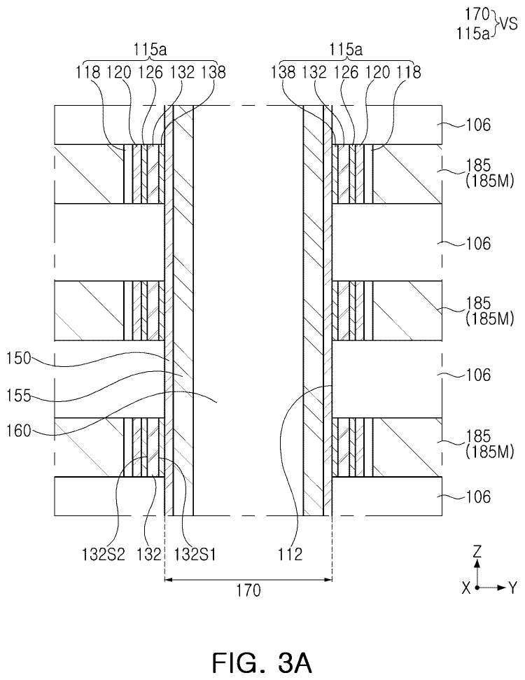

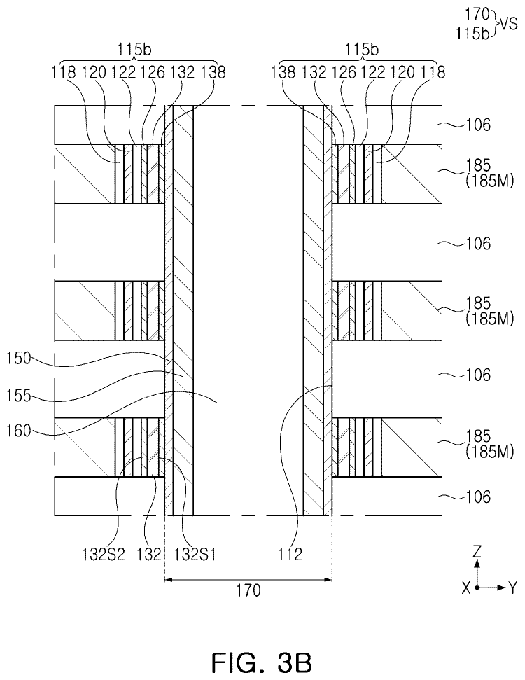

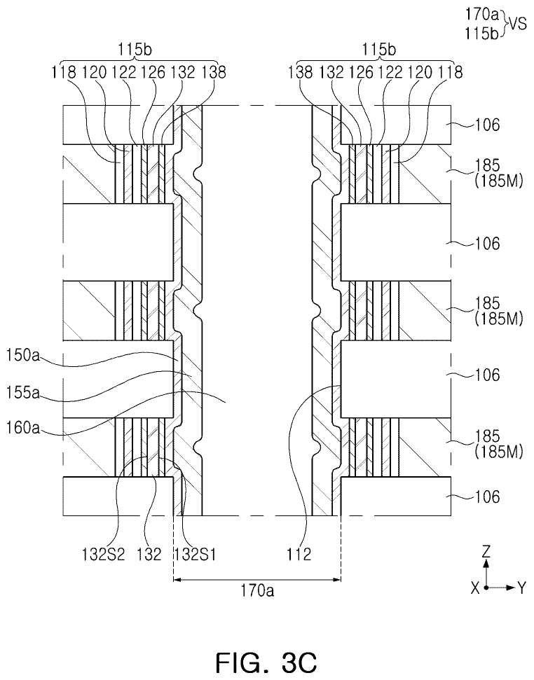

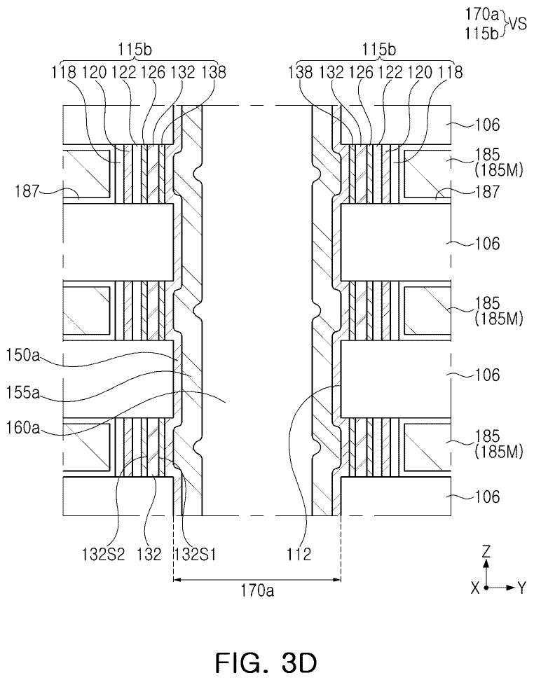

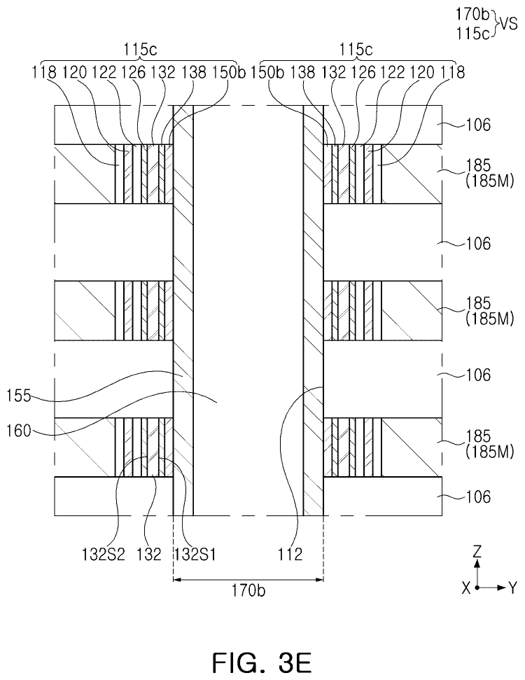

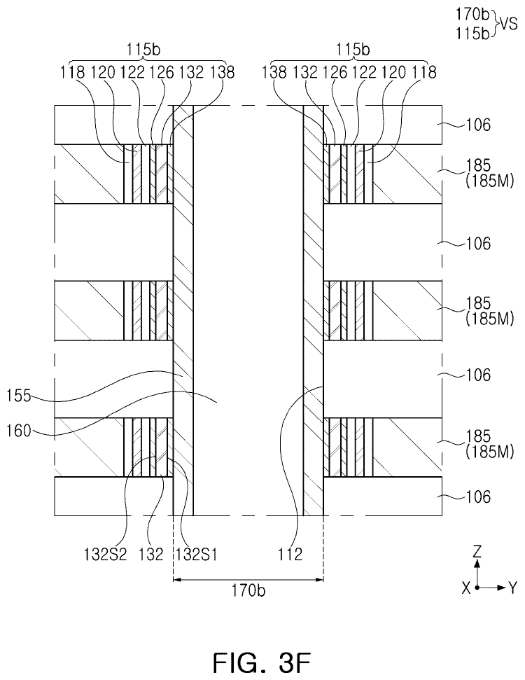

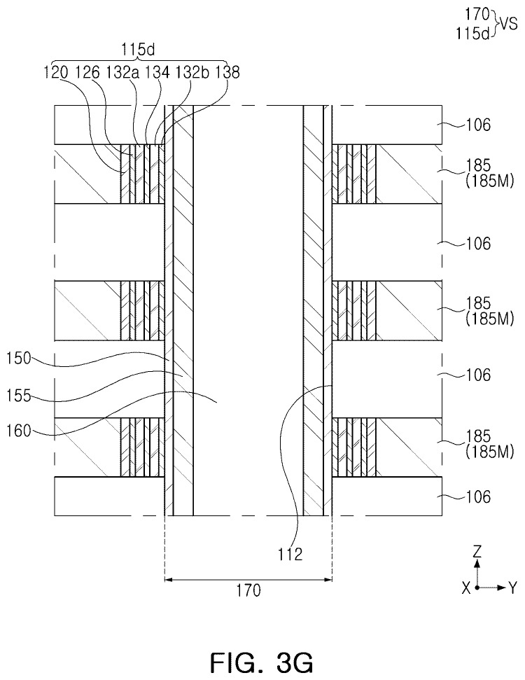

Hereinafter, various modified examples of the components in the aforementioned example embodiment will be described with reference to FIGS. 3A to 9. Various modified examples of the components of the above-described example embodiment described below will be described with respect to modified components or replaced components. Here, the components described above may be quoted directly without detailed description, or the description may not be provided.

Also, the components which may be modified or replaced described below may improve at least one of connectivity, reliability, performance, and productivity of the semiconductor device.

Also, the modified or replaced components described below will be described with reference to the drawings, but the modified or replaced components may be combined with each other or with the components described above and may be included in the semiconductor device according to example embodiments.

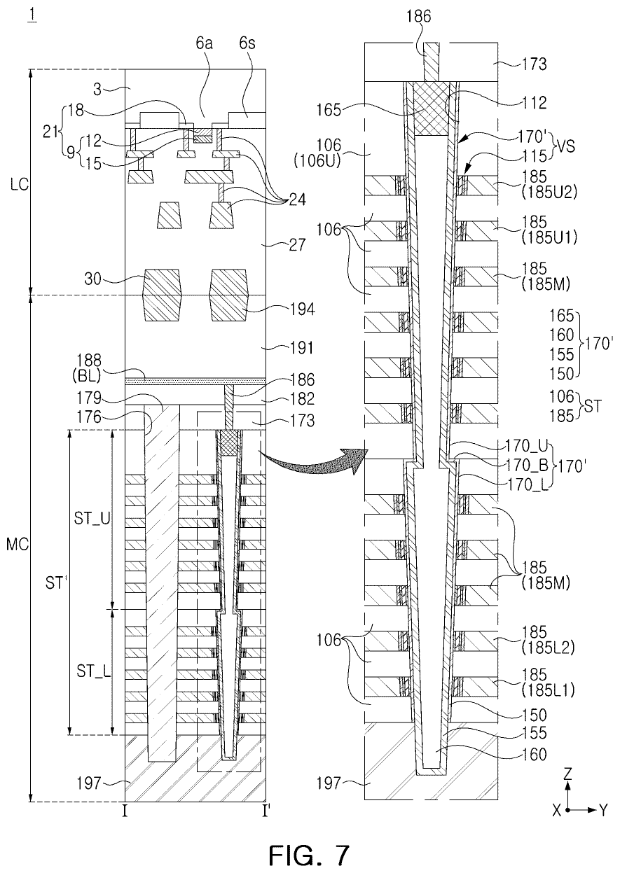

FIGS. 3A to 3G, 4A to 4G, 5, and 6A to 6F are enlarged diagrams corresponding to FIG. 2B, and FIGS. 7, 8, and 9 are cross-sectional diagrams illustrating region taken along line I-I′ in FIG. 1.

In the modified example, referring to FIG. 3A, the protrusions (115 in FIG. 2B) described above may be modified to protrusions 115a further including a first insulating layer 118. In each of the protrusions 115a, the first insulating layer 118 may be disposed between the gate electrode 185 and the first data storage layer 120, and may be in contact with the first data storage layer 120. The first insulating layer 118 may include SiO2, SiN, SiON, (Hf, Zr, Al, C, N, Gd, Y, Ti, La, Ta)-doped Si (O) N or a combination thereof, but an example embodiment thereof is not limited thereto, and for example, the first insulating layer 118 may include a single layer or multiple layers of the materials mentioned above.

In another example, the positions of the first data storage layer 120 and the second conductive layer 126 may be exchanged. For example, the first data storage layer 120 may be modified to be disposed between the second conductive layer 126 and the second data storage layer 132.

In the modified example, referring to FIG. 3B, the protrusions (115a in FIG. 3a) described above may be modified to protrusions 115b further including a second insulating layer 122. In each of the protrusions 115b, the second insulating Layer 122 may be disposed between the first data storage layer 120 and the second conductive layer 126. The second insulating layer 122 may be in contact with the first data storage layer 120 and the second conductive layer 126. The second insulating layer 122 may be formed of SiO2, SiN, SiON, (Hf, Zr, Al, C, N, Gd, Y, Ti, La, Ta)-doped Si (O) N, or a combination thereof, but an example embodiment thereof is not limited thereto, and for example, the second insulating layer 122 may include a single layer or multiple layers formed of the materials mentioned above.

In the modified example, referring to FIG. 3C, the aforementioned vertical pillar (170 in FIG. 2B) may be modified into a vertical pillar 170a of which a width may increase on the same level as a level of the gate electrodes 185. The vertical pillar 170a may have a first width on the same level as a level of the interlayer insulating layers 106, and may have a second width greater than the first width on the same level as a level of the gate electrodes 185.

The interfacial insulating layer (150 in FIG. 2B) described above may be modified into an interfacial insulating layer 150a bent in a direction toward the gate electrodes 185. The aforementioned channel layer (155 in FIG. 2B) may be modified into a channel layer 155a bent in a direction toward the gate electrodes 185. The insulating core region (160 in FIG. 2B) described above may be modified into an insulating core region 160a having portions protruding in a direction toward the gate electrodes 185.

FIG. 3C illustrates the protrusions 115b described in FIG. 3B, but the protrusion 115b may be replaced with the protrusion 115 in FIG. 2B or the protrusion 115a in FIG. 3A. In the modified example embodiments described below, the description of the components described above may not be provided.

In the modified example, referring to FIG. 3D, dielectric layers 187 covering the upper surface and the lower surface of each of the gate electrodes 185 and covering the side surfaces of the gate electrodes 185 opposing the protrusions 115b may be disposed. The dielectric layers 187 may be in contact with the gate electrodes 185 and the protrusions 115b between the gate electrodes 185 and the protrusions 115b. The dielectric layers 187 may include at least one of silicon oxide and high-K dielectric.

In the modified example, referring to FIG. 3E, the aforementioned vertical pillar (170 in FIG. 2B) may be modified to a vertical pillar 170b in which the interfacial insulating layer (150 in FIG. 2B) is not provided. The protrusions (115 in FIG. 2B, 115a in FIGS. 3A, and 115b in FIGS. 3B to 3D) in the example embodiments described above may be modified into protrusions further including an interfacial insulating layer 150b in contact with the channel layer 155 of the vertical pillar 170b. For example, the protrusions (115b in FIG. 3B) in the example embodiments described above may be modified into protrusions 115c further including an interfacial insulating layer 150b in contact with the channel layer 155 of the vertical pillar 170b.

In the modified example, referring to FIG. 3F, the vertical pillar (170 in FIG. 2B) described above may be modified to a vertical pillar 170b in which the interfacial insulating layer (150 in FIG. 2B) is not provided, and the channel layer 155 of the vertical pillar 170b may be in contact with the protrusions (115 in FIG. 2B, 115a in FIGS. 3A, and 115b in FIGS. 3B to 3D) in the example embodiments described above. For example, the channel layer 155 of the vertical pillar 170b may be in contact with the protrusions 115b described above (the first conductive layers 138 of 115b in FIG. 3B).

In the modified example, referring to FIG. 3G, the second data storage layer (132 in FIGS. 2B to 3F) of the protrusions (115 in FIG. 2B, 115a in FIG. 3A, 115b in FIGS. 3B to 3D and 3F, 115c in FIG. 3E) in each of the example embodiments described above may be replaced with a data storage structure including ferroelectric layers and conductive layers alternately stacked in the direction from the gate electrodes 185 to the channel layer 155. The second data storage layer (132 in FIGS. 2B to 3F) may be replaced with a data storage structure including a first sub-data storage layer 132a, an intermediate conductive layer 134, and a second sub-data storage layer 132b disposed in order from the gate electrodes 185 toward the channel layer 155. Here, the first and second sub-data storage layers 132a and 132b may be configured as ferroelectric layers, and the intermediate conductive layer 134 may include the same material as that of at least one of the first and second conductive layers 138 and 126. Accordingly, the protrusions (115 in FIG. 2B, 115a in FIG. 3A, 115b in FIGS. 3B to 3D and 3F, 115c in FIG. 3E) may be modified to protrusions 115d including the first sub-data storage layer 132a, the intermediate conductive layer 134, and the second sub-data storage layer 132b.

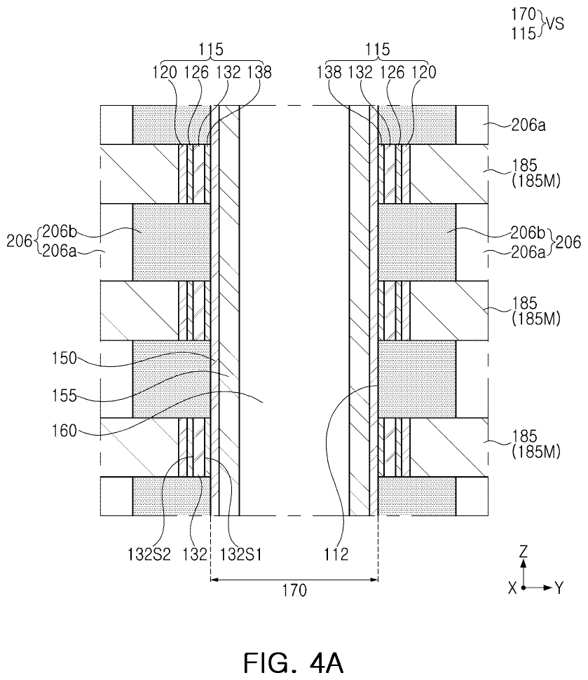

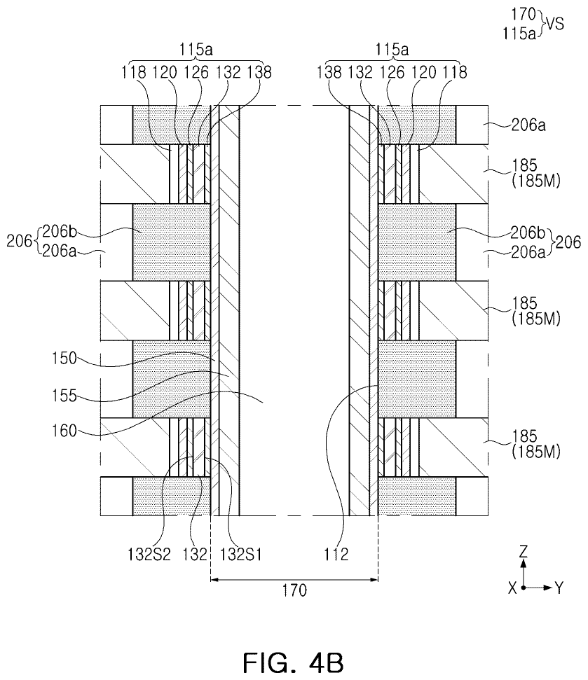

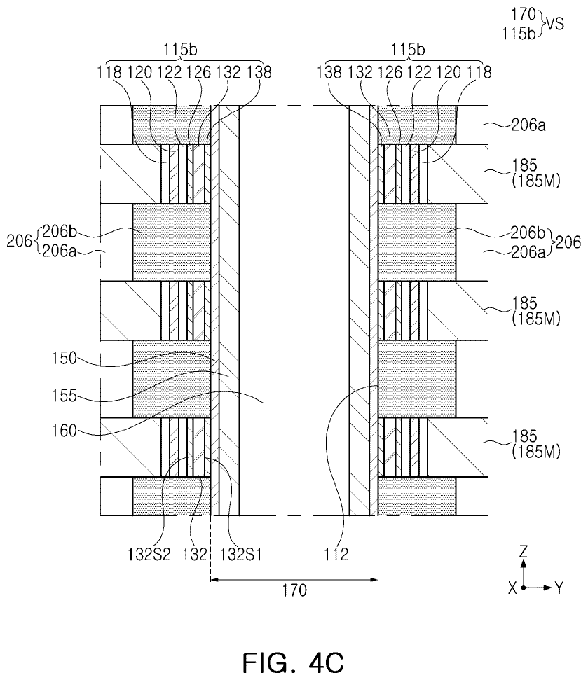

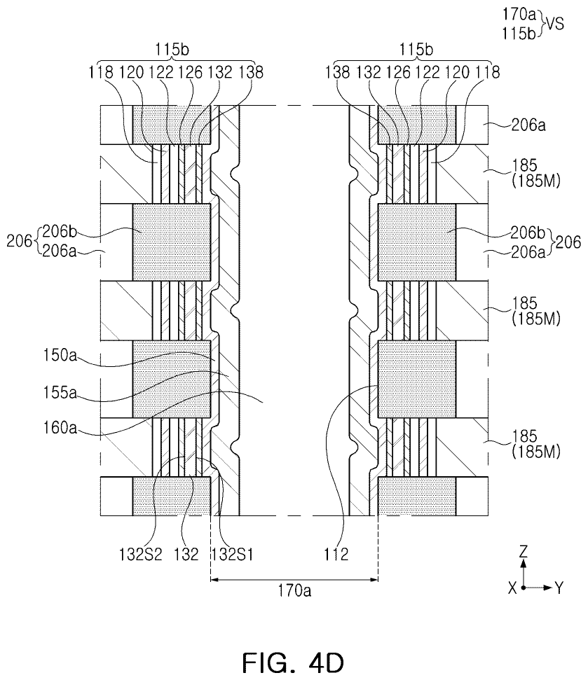

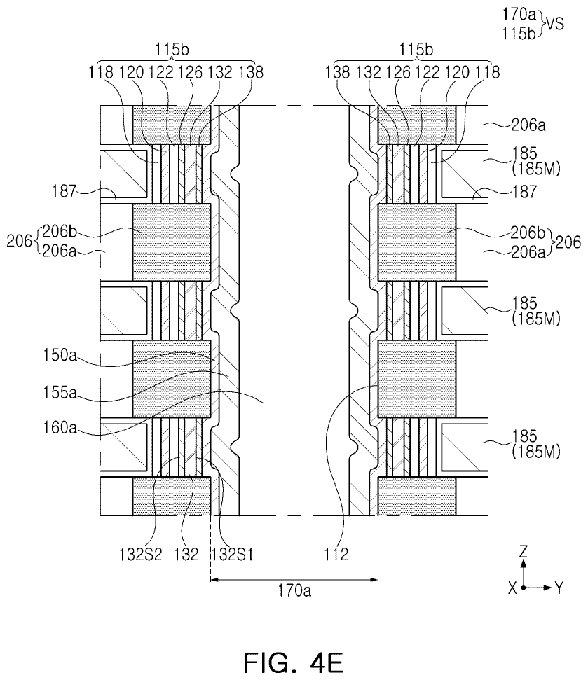

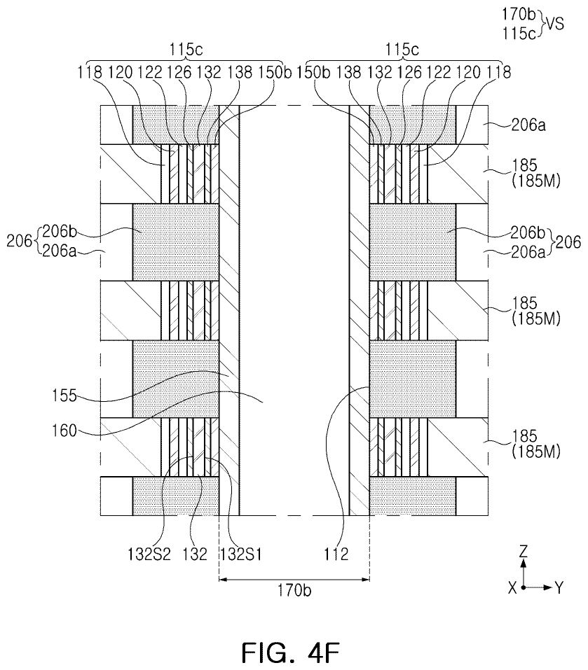

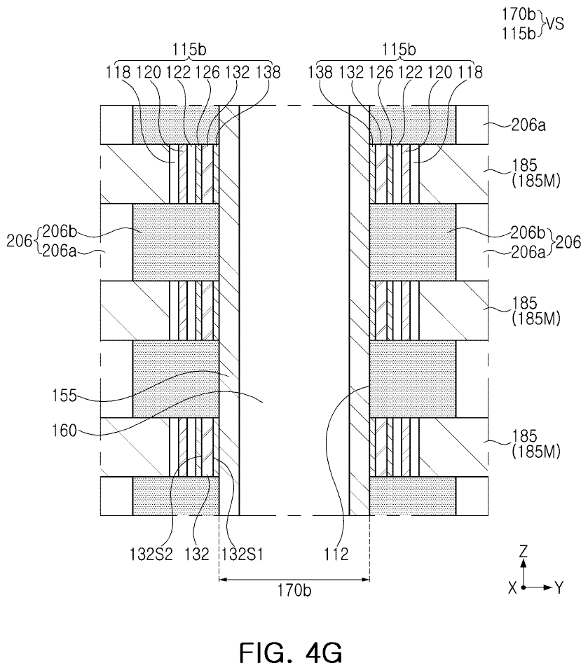

In the modified example, referring to FIG. 4A, each of the interlayer insulating layers (106 in FIG. 2B) in FIG. 2B may be replaced with interlayer insulating layers 206 including a first insulating portion 206a and a second insulating portion 206b between the first insulating portion 206a and the vertical pillar 170.

Among the protrusions 115 and the gate electrodes 185, portions adjacent to the protrusions 115 may vertically overlap the second insulating portions 206b. Each of the protrusions 115 may be disposed between the second insulating portions 206b adjacent to each other in the vertical direction Z.

A width of each of the protrusions 115 may be smaller than a width of each of the second insulating portions 206b in the horizontal direction perpendicular to the vertical direction Z.

The first insulating portion 206a may include silicon oxide. The second insulating portion 206b may be formed of SiO₂, SiON, Al₂O₃, Ta₂O₅, HfO₂, ZrO₂, HfSiOₓ, ZrSiOₓ, SiNₓ, or a combination thereof, but an example embodiment thereof is not limited thereto, and for example, the second insulating portion 206b may include a single layer or multiple layers of the materials mentioned above.

In an example, the second insulating portion 206b may be formed of the same material as that of the first insulating portion 206a.

In another example, the second insulating portion 206b may be formed of a different material from that of the first insulating portion 206a.

In the modified example, referring to FIG. 4B, each of the interlayer insulating layers (106 in FIG. 3A) in FIG. 3A may be replaced with the interlayer insulating layers 206 including the first insulating portion 206a and the second insulating portion 206b described in FIG. 4A.

In the modified example, referring to FIG. 4C, each of the interlayer insulating layers (106 in FIG. 3A) in FIG. 3B may be replaced with the interlayer insulating layers 206 including the first insulating portion 206a and the second insulating portion 206b described in FIG. 4A.

In the modified example, referring to FIG. 4D, each of the interlayer insulating layers (106 in FIG. 3A) in FIG. 3C may be replaced with the interlayer insulating layers 206 including the first insulating portion 206a and the second insulating portion 206b described in FIG. 4A.

In the modified example, referring to FIG. 4E, each of the interlayer insulating layers (106 in FIG. 3A) in FIG. 3D may be replaced with the interlayer insulating layers 206 including the first insulating portion 206a and the second insulating portion 206b described in FIG. 4A.

In the modified example, referring to FIG. 4F, each of the interlayer insulating layers (106 in FIG. 3A) in FIG. 3E may be replaced with the interlayer insulating layers 206 including the first insulating portion 206a and the second insulating portion 206b as described in FIG. 4A.

In the modified example, referring to FIG. 4G, each of the interlayer insulating layers (106 in FIG. 3A) in FIG. 3F may be replaced with the interlayer insulating layers 206 including the first insulating portion 206a and the second insulating portion 206b as described in FIG. 4A.

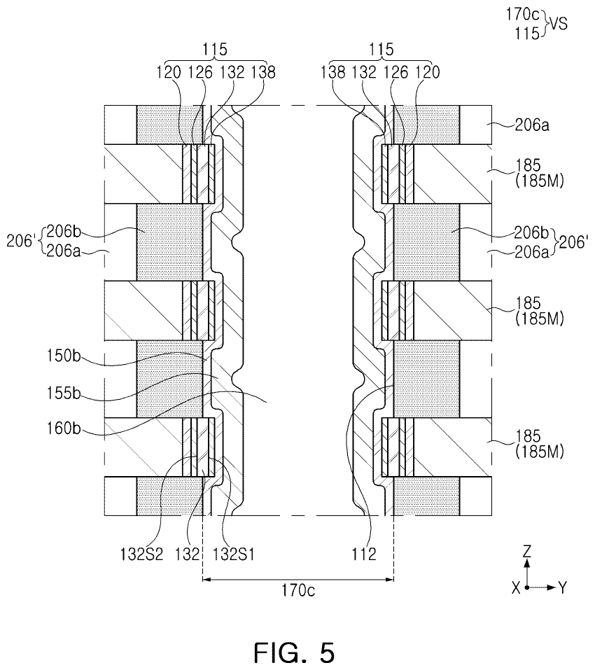

In the modified example, referring to FIG. 5, the interlayer insulating layers (106 in FIGS. 2B to 3G and 206 in FIGS. 4A to 4G) described above may be modified into recessed interlayer insulating layers 206′.

The vertical pillar (170 in FIGS. 2B to 4G) described above may be modified into a vertical pillar 170C having an increased width on the same level as a level of the interlayer insulating layers 206′. The vertical pillar 170C may have a first width on the same level as a level of the gate electrodes 185, and may have a second width greater than the first width on the same level as a level of the interlayer insulating layers 206′. The interfacial insulating layer (150 in FIG. 2b) described above may be modified into an interfacial insulating layer 150a bent in a direction toward the gate electrodes 185. The channel layer (155 in FIG. 2b) described above may be modified into a channel layer (155b) bent in a direction toward the interlayer insulating layers 206′. The insulating core region (160 in FIG. 2b) described above may be modified into an insulating core region 160b having portions protruding in a direction toward the interlayer insulating layers 206′.

The protrusions described above (115, 115b, 115c, 115d in FIGS. 2B to 4G) may have a shape protruding in a direction toward the insulating core region 160b rather than the interlayer insulating layers 206′. In each of the protrusions described above (115, 115b, 115c, 115d in FIGS. 2B to 4G), a portion of components, for example, the first conductive layer 138, may not vertically overlap the interlayer insulating layers 206′.

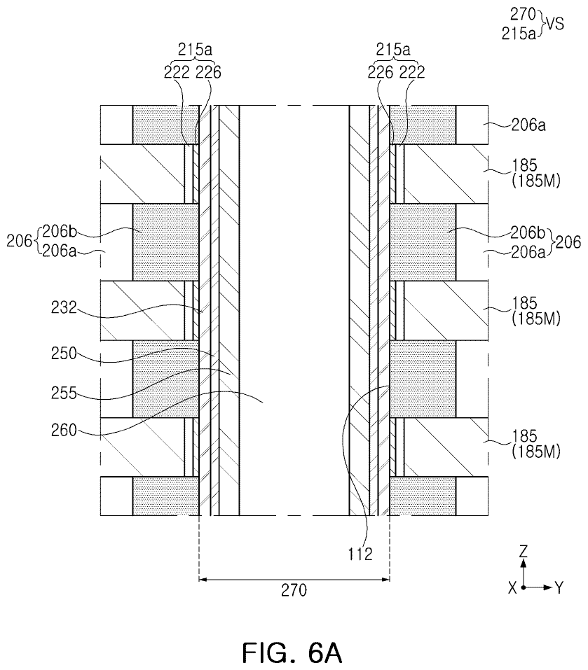

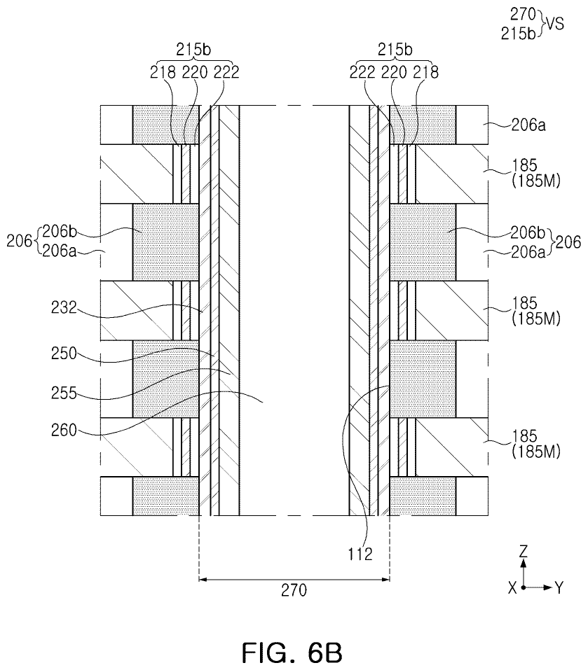

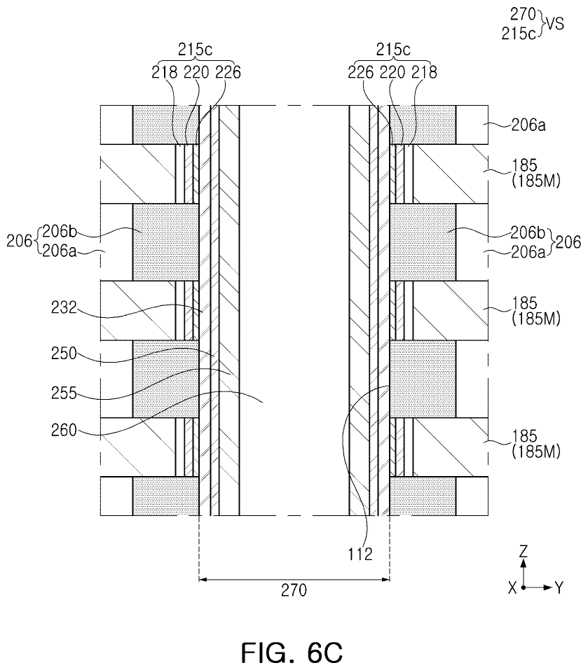

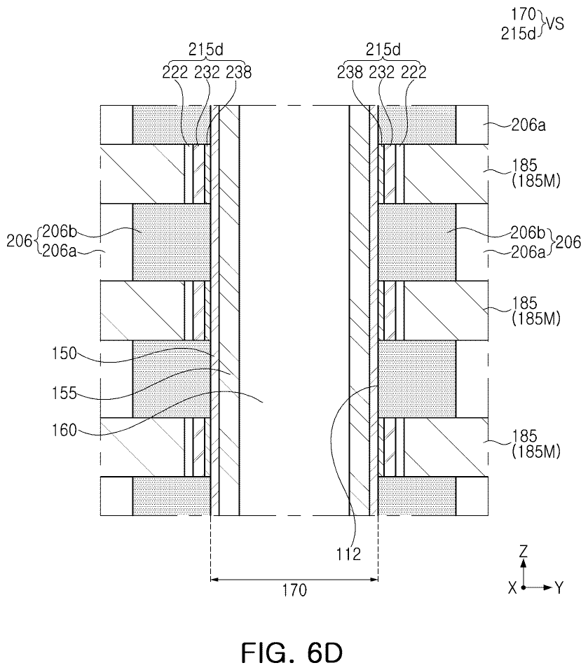

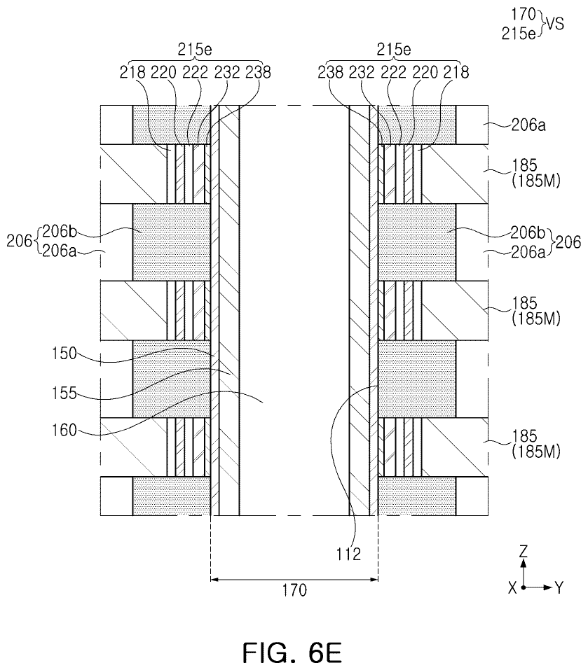

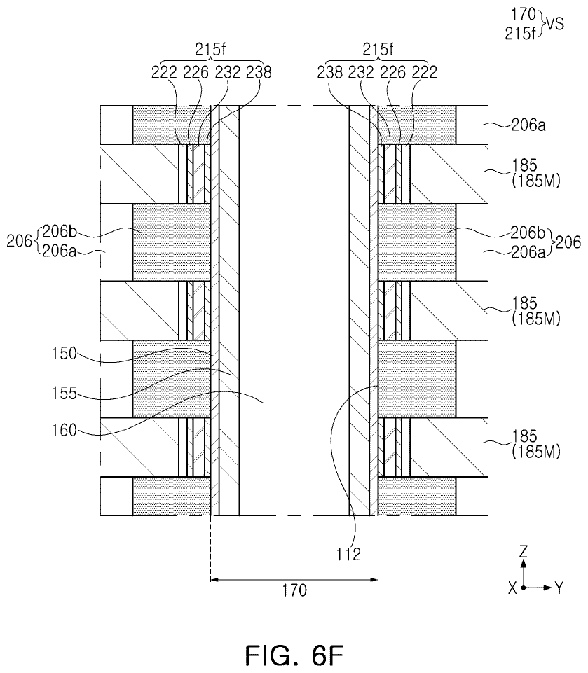

In the modified example, referring to FIG. 6A, the vertical pillar (170 in FIG. 2B) described above may be replaced with a vertical pillar 270 further including a second data storage layer 232. For example, the vertical pillar 270 may include an insulating core region 260, a channel layer 255 and an interfacial insulating layer 250 corresponding to the insulating core region (160 in FIG. 2B), the channel layer 155 and the interfacial insulating layer 150, respectively, and the second data storage layer 232 of the vertical pillar 270 may be disposed on the external side surface of the interfacial insulating layer 226. The data storage layer 232 may be the same material as that of the second data storage layer (132 in FIG. 2B) described above. For example, the second data storage layer 232 may be configured as a ferroelectric layer.

In example embodiments, the interfacial insulating layer 250 may not be provided.

The protrusions (115 in FIG. 2b) described above may be replaced with protrusions 215a including the second insulating layer 222 and the first conductive layer 226. The second insulating layer 222 may be the same material as that of the second insulating layer (122 in FIG. 3B) described above. The first conductive layer 226 may be the same material as that of the second conductive layer (126 in FIG. 2B) described above.

The first conductive layer 226 may be disposed between the second insulating layer 222 and the second data storage layer 232. The first conductive layer 226 may be in contact with the second insulating layer 222 and the second data storage layer 232, between the second insulating layer 222 and the second data storage layer 232.

FIG. 6A illustrates the interlayer insulating layers 206 described in FIG. 4A, but an example embodiment thereof is not limited thereto. For example, the interlayer insulating layers 206 illustrated in FIG. 6A may be replaced with the interlayer insulating layers 106 illustrated in FIG. 2B. Similarly, FIGS. 6B to 6F illustrate the interlayer insulating layers 206 described in FIG. 4A, but the interlayer insulating layers 206 illustrated in FIGS. 6B to 6F may be replaced with the interlayer insulating layers 106 as in FIG. 2B.

The protrusions 215a may be spaced apart from each other in the vertical direction Z by the second insulating portions 206b of the interlayer insulating layers 206.

In the modified example, referring to FIG. 6B, the protrusions (215a in FIG. 6A) described in FIG. 6A may be replaced with protrusions 215b including the first insulating layer 218, the first data storage layer 220 and the second insulating layer 222. The first data storage layer 220 may be disposed between the first insulating layer 218 and the second insulating layer 222 and may be in contact with the first insulating layer 218 and the second insulating layer 222. The second insulating layer 222 may be in contact with the vertical pillar 270. The first insulating layer 218 may be the same material as that of the first insulating layer (118 in FIG. 3A) described above, and the second insulating layer 222 may be the same material as that of the second insulating layer (122 in FIG. 3B) described above. The first data storage layer 220 may be the same material as that of the first data storage layer (120 in FIG. 2B) described above.

In the modified example, referring to FIG. 6C, the protrusions (215b in FIG. 6B) described above may be replaced with protrusions 215C including the first insulating layer 218, the first data storage layer 220 and the second conductive layer 226. The first data storage layer 220 may be disposed between the first insulating layer 218 and the second conductive layer 226 and may be in contact with the first insulating layer 218 and the second conductive layer 226. The second conductive layer 226 may be in contact with the second data storage layer 232 of the vertical pillar 270. The first insulating layer 218 may be the same material as that of the first insulating layer (118 in FIG. 3A) described above, and the second conductive layer 226 may be the same material as that of the second conductive layer (126 in FIG. 2B) described above. The first data storage layer 220 may be the same material as that of the first data storage layer (120 in FIG. 2B) described above.

In the modified example, referring to FIG. 6D, the protrusions (115 in FIG. 2B) described above may be replaced with protrusions 215d including a second insulating layer 222, a second data storage layer 232 and a first conductive layer 238. The second data storage layer 232 may be disposed between the second insulating layer 222 and the first conductive layer 238 and may be in contact with the second insulating layer 222 and the first conductive layer 238. The first conductive layer 238 may be in contact with the vertical pillar (170 in FIG. 2B) as described above.

The second insulating layer 222 may be the same material as that of the second insulating layer (122 in FIG. 3B) described above, and the second data storage layer 232 may be the same material as that of the second data storage layer (132 in FIG. 2B) described above. For example, the second data storage layer 232 may be configured as a ferroelectric layer. The first conductive layer 238 may be the same material as that of the first conductive layer (138 in FIG. 2b) described above.

In the modified example, referring to FIG. 6E, the protrusions (215d in FIG. 6D) described in FIG. 6D may be modified to protrusions 212e, which further may include a first insulating layer 218 and a first data storage layer 220. In the protrusions 212e, the first data storage layer 220 may be disposed between the first insulating layer 218 and the second insulating layer 222. The first insulating layer 218 may be the same material as that of the first insulating layer (118 in FIG. 3A) described above, and the first data storage layer 220 may be the same material as that of the first data storage layer (120 in FIG. 2B) described above.

In the modified example, referring to FIG. 6F, the protrusions (215d in FIG. 6D) described in FIG. 6D may be modified to protrusions 215f further including a second conductive layer 226 between the second insulating layer 222 and the second data storage layer 232. The second conductive layer 226 may be in contact with the second insulating layer 222 and the second data storage layer 232 between the second insulating layer 222 and the second data storage layer 232. The second conductive layer 226 may be the same material as that of the second conductive layer (126 in FIG. 2B) described above.

In the modified example, referring to FIG. 7, the aforementioned stack structure (ST in FIG. 2A) may be modified to stack structure ST′ including a lower stack structure ST_L and an upper stack structure ST_U. each of the lower stack structure ST_L and the upper stack structure ST_U may include interlayer insulating layers 106 and gate electrodes 185 alternately stacked.

Among the gate electrodes 185, the lower stack structure ST_L may include the lower gate electrodes 185L1, 185L2 and the intermediate gate electrodes 185M as described above, and the upper stack structure ST_U may include the upper gate electrodes 185U1, 185U2 and the intermediate gate electrodes 185M as described above.

The vertical pillar (170 in FIG. 2A) described above may be modified to a vertical pillar 170′ including a lower vertical pillar 170_L penetrating through the lower stack structure ST_L, an upper vertical pillar 170_U penetrating through the upper stack structure ST_U, and a bent portion 170_B between the lower vertical pillar 170_L and the upper vertical pillar 170_U.

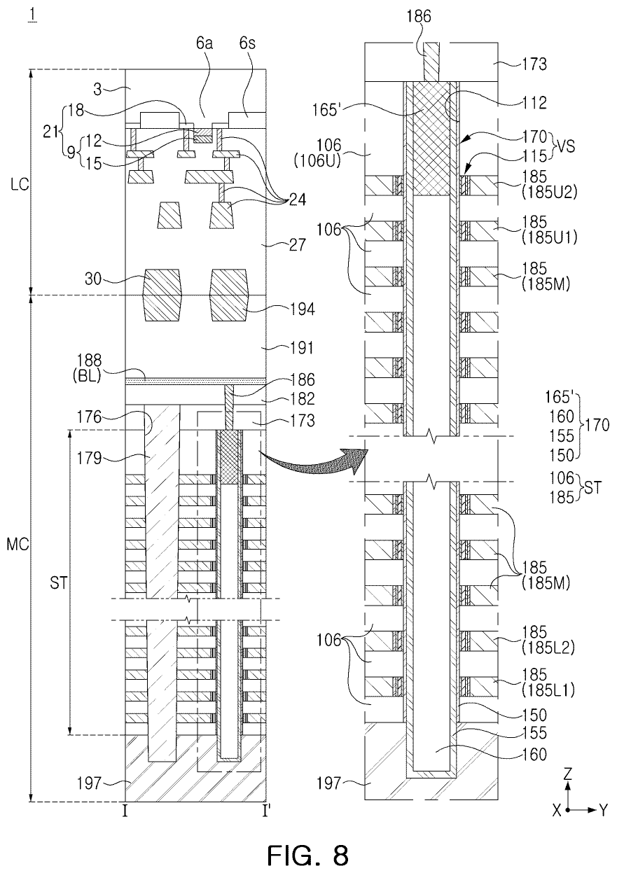

In the modified example, referring to FIG. 8, when the second upper gate electrode 185U2 is an erase control gate electrode, the pad pattern (165 in FIG. 2A) described above may be modified to a pad pattern 165′ having a portion disposed on the same level as a level of at least a portion of the second upper gate electrode 185U2 to improve the erase operation. A lower surface of the pad pattern 165′ may be disposed on a level higher than a level of the intermediate gate electrodes 185M and may be disposed on a level lower than a level of the upper surface of the second upper gate electrode 185U2.

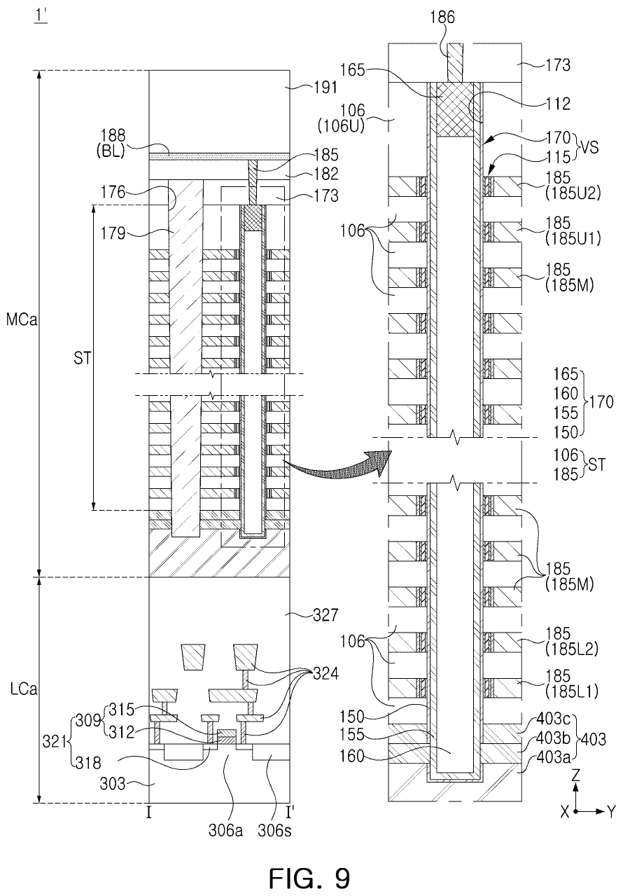

In the modified example, referring to FIG. 9, in the first region (MC in FIG. 2a) and the second region (LC in FIG. 2a) described above, two chips may be bonded to each other by metal-to-metal bonding, but an example embodiment thereof is not limited thereto. For example, the first region (MC in FIG. 2A) and the second region (LC in FIG. 2A) described above may be replaced with the first region MCa and the second region LCa disposed in a chip. For example, the second region LCa may be disposed below the first region MCa and may vertically overlap the first region MCa.

The second region LCa may include a substrate 303, a device isolation region 306S defining an active region 306a on the substrate 303, a peripheral circuit 321 on the substrate 303, a circuit interconnection structure 324 on the peripheral circuit 321, and a peripheral insulating structure 327 covering the peripheral circuit 321 and the circuit interconnection structure 324 on the substrate 303.

The peripheral circuit 321 may include a transistor including a peripheral gate 309 on the active region 306a, and peripheral source/drain regions 318 disposed in the active region 306a on both sides of the peripheral gate 309. The peripheral gate 309 may include a peripheral gate dielectric layer 312 and a peripheral gate electrode 315 on the peripheral gate dielectric layer 312.

The first region MCa may include the stack structure ST, the vertical structure VS, the first and second upper insulating layers 173 and 191, the contact plug 186, and the conductive line 188 described above. The first region MCAA may further include a lower pattern 403, which may replace the lower pattern (197 in FIG. 2A) described above.

The lower pattern 4003 may include a first layer 403a, a second layer 403b, and a third layer 403C, stacked in order.

The first layer 403a may include at least one of a doped polysilicon layer and a metal layer. For example, the first layer 403a may include a polysilicon layer having N-type conductivity. The second layer 403b may include doped polysilicon, for example, polysilicon having N-type conductivity. The third layer 403C may include doped polysilicon, for example, polysilicon with N-type conductivity. The lower pattern 403 may be configured as a common source.

The vertical pillar 170 may extend into the lower pattern 403 from a portion penetrating through the stack structure ST.

The channel layer 155 of the vertical pillar 170 may cover a side surface and a lower surface of the insulating core region 160, and the interfacial insulating layer of the vertical pillar 170 150 may cover an external side surface and a lower surface of the channel layer 155 on a level lower than a level of an upper surface of the lower pattern 403. The second layer 403b of the lower pattern 403 may penetrate through the interfacial insulating layer 150 and may be connected to the channel layer 155.

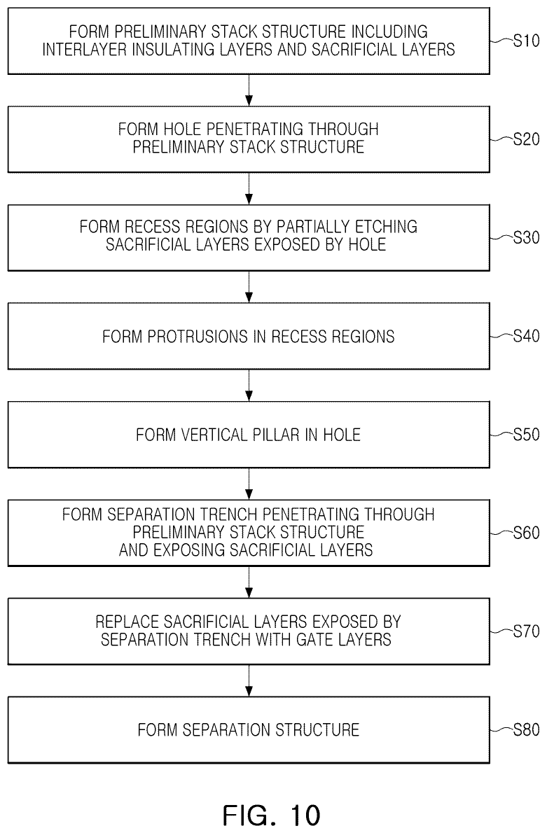

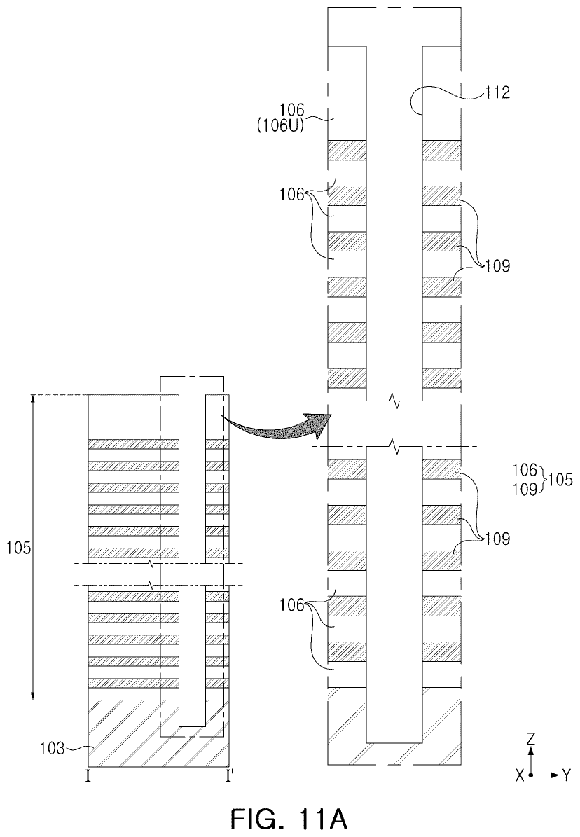

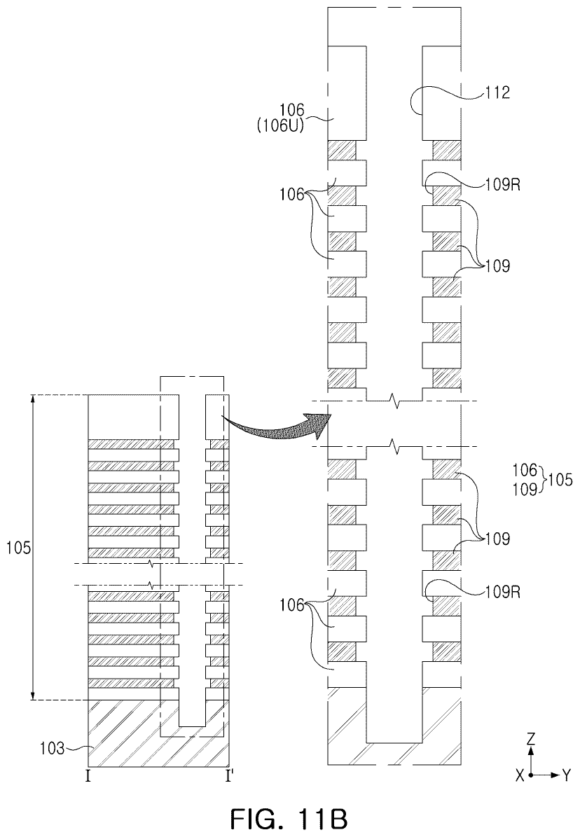

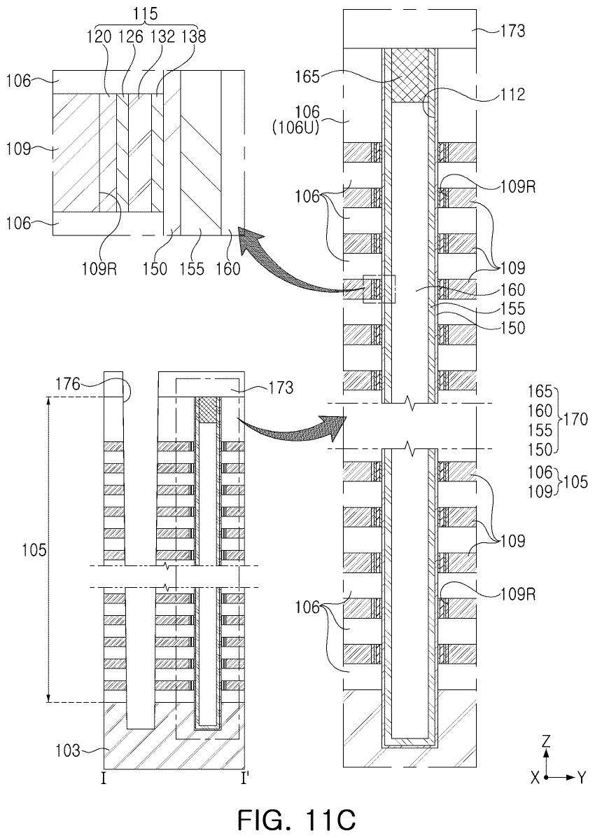

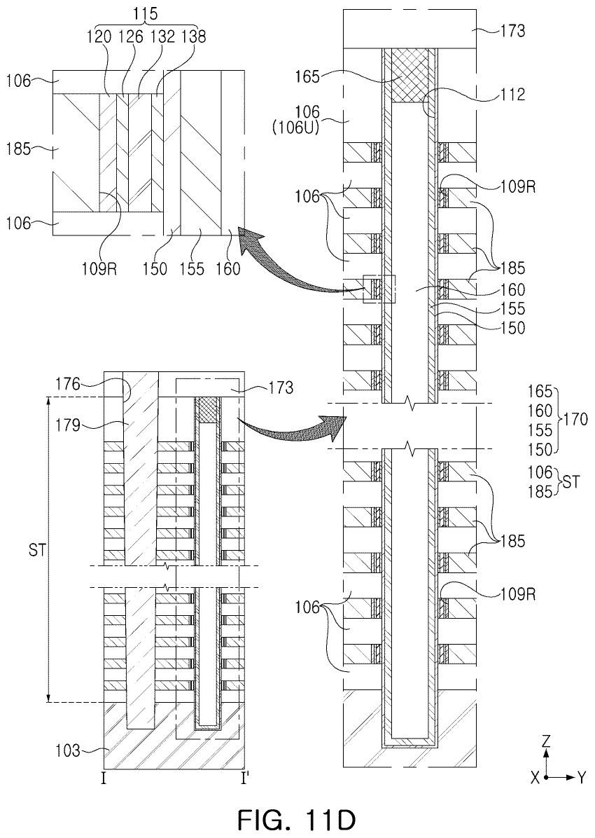

Thereafter, an example of a method of manufacturing a semiconductor device according to an example embodiment will be described with reference to FIGS. 10 and 11A to 11D. FIG. 10 is a flowchart illustrating an example of a method of manufacturing a semiconductor device according to an example embodiment, and FIGS. 11A to 11D are cross-sectional diagrams illustrating an example of a method of manufacturing a semiconductor device according to an example embodiment, illustrating region taken along line I-I′ in FIG. 1.

Referring to FIGS. 10 and 11A, a substrate 103 may be prepared. A preliminary stack structure 105 including interlayer insulating layers 106 and sacrificial layers 109 may be formed (S10). The preliminary stack structure 105 may be formed on the substrate 103. The interlayer insulating layers 106 and the sacrificial layers 109 may be alternately stacked. The interlayer insulating layers 106 may be formed of a material different from that of the sacrificial layers 109. For example, the interlayer insulating layers 106 may be formed of silicon oxide, and the sacrificial layers 109 may be formed of silicon nitride.

A hole 112 penetrating through the preliminary stack structure 105 may be formed (S20). The hole 112 may extend into the substrate 103.

Referring to FIGS. 10 and 11B, recess regions 109R may be formed by partially etching the sacrificial layers 109 exposed by the hole 112 (S30).

Referring to FIGS. 10 and 11C, protrusions 115 may be formed in the recess regions 109R (S40). The protrusions 115 may also be referred to as protrusions.

The forming the protrusions 115 may include repeating a deposition process for depositing a material layer and a pullback process for partially etching the material layer using an isotropic etching process. For example, the forming the protrusions 115 may include repeatedly performing a process of forming a material layer filling at least the recess regions 109R, and forming a material layer remaining with a desired thickness in the recess regions 109R by performing a pullback process to partially etch the material layer using an isotropic etching process. The protrusions 115 may include the first data storage layer 120, the second conductive layer 126, the second data storage layer 132 and the first conductive layer 138 as in FIGS. 2A and 2B, but an example embodiment thereof is not limited thereto. For example, the protrusions 115 may be formed as the protrusions 115a, 115b, 115c, and 115d as described in FIGS. 3A to 3G.

The vertical pillar 170 may be formed in the hole 112 (S50). The forming the vertical pillar 170 may include sequentially forming an interfacial insulating layer 150 and a channel layer 155 covering the internal wall of the hole 112 and the protrusions 115, forming an insulating core region 160 partially filling the hole 112 in the channel layer 155, and forming a pad pattern 165 on the insulating core region 160.

The vertical pillar 170 and the protrusions 115 may form a vertical structure.

A separation trench 176 penetrating through the preliminary stack structure 105 and exposing the sacrificial layers 109 may be formed (S60).

Before forming the separation trench 176, a first upper insulating layer 173 may be formed on the vertical structure and the preliminary stack structure 105. When the first upper insulating layer 173 is formed, the separation trench 176 may penetrate through the first upper insulating layer 173 and the preliminary stack structure 105.

Referring to FIGS. 10 and 11D, the sacrificial layers 109 exposed by the separation trench 176 may be replaced with gate layers 185 (S70). For example, voids may be formed by removing the sacrificial layers 109 exposed by the separation trench 176, and the gate layers 185 filling the voids may be formed. The gate layers 185 may be configured as gate electrodes.

A separation structure 179 filling the separation trench 176 may be formed (S80).

Referring back to FIGS. 1 to 2B, a contact plug 186 penetrating through the first and second upper insulating layers 173 and 182 and electrically connected to the pad pattern 165 of the vertical structure VS, a third upper insulating layer 191 on the second upper insulating layer 182 and the conductive line 188, and a first bonding pads 194 having an upper surface coplanar with and upper surface of the third upper insulating layer 191 and having a side surface surrounded by the third upper insulating layer 191 may be formed.

Thereafter, a semiconductor chip of the second region LC may be formed. The semiconductor chip of the second region LC may include a substrate 3, a device isolation region 6s defining an active region 6a on the substrate 3, a peripheral circuit 21 on the substrate 3, a circuit interconnection structure 24 on the peripheral circuit 21, a peripheral insulating structure 27 covering the peripheral circuit 21 and the circuit interconnection structure 24 on the substrate 3, and a second bonding pads 30 having a side surface surrounded by the peripheral insulating structure 27 and a lower surface coplanar with the lower surface of the peripheral insulating structure 27.

The second bonding pads 30 and the first bonding pads 194 of the second region LC may be bonded to each other by performing an inter-metal bonding process.

Thereafter, the substrate (103 in FIG. 11D) may be removed to expose at least the vertical pillar 170, the channel layer 155 may be exposed by etching the interfacial insulating layer 150 of the vertical pillar 170 exposed by removing the substrate (103 in FIG. 11D), and a lower pattern 197 in contact with the channel layer 155 may be formed. Accordingly, the semiconductor device 1 as described in FIGS. 1 to 2B may be formed.

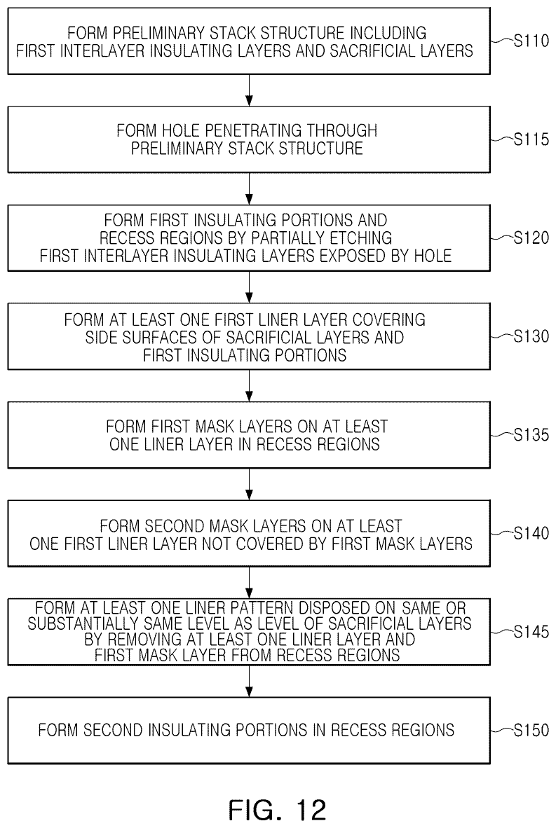

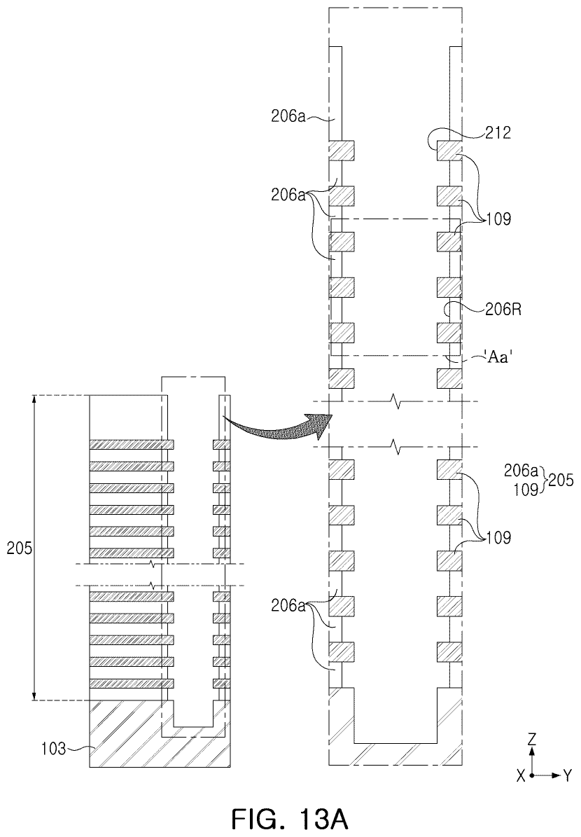

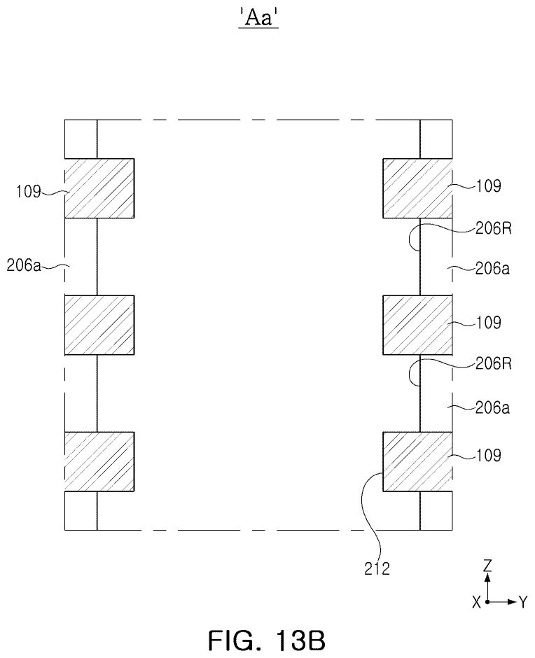

In the description below, another example of a method of manufacturing a semiconductor device according to an example embodiment will be described with reference to FIGS. 12, 13A, 13B, 14A to 14C, and 15A to 15E. FIG. 12 is a flowchart illustrating another example of the method of manufacturing a semiconductor device according to an example embodiment, FIG. 13A is a cross-sectional diagram illustrating another example of the method of manufacturing a semiconductor device according to an example embodiment, illustrating a region taken along line I-I′ in FIG. 1, and FIGS. 13B, 14A to 14C, and 15A to 15E enlarged diagrams corresponding to region “Aa,” illustrating another example of the method of manufacturing a semiconductor device according to an example embodiment.

Referring to FIGS. 12, 13A, and 13B, substrate 103 may be prepared. A preliminary stack structure 205 including interlayer insulating layers and sacrificial layers 109 (S110). The preliminary stack structure 205 may be formed on the substrate 103. The interlayer insulating layers and the sacrificial layers 109 may be alternately stacked. A hole 212 penetrating through the preliminary stack structure 205 may be formed (S115). The hole 212 may extend into the substrate 103. The interlayer insulating layers exposed by the hole 212 may be partially etched and may form first insulating portions 206a and recess regions 206R (S120).

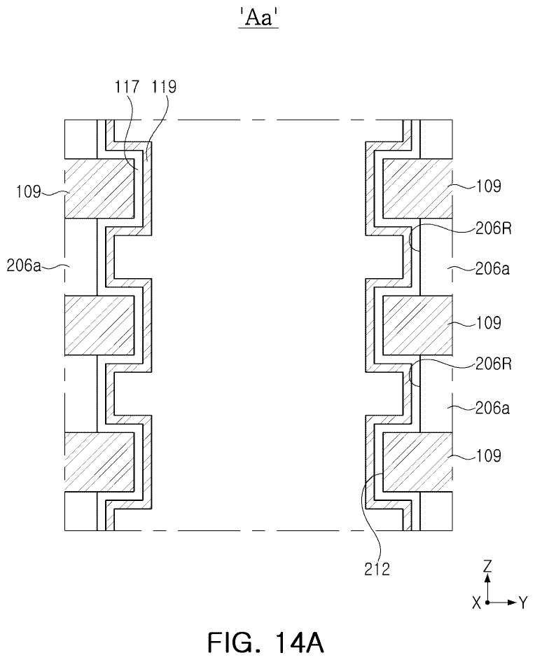

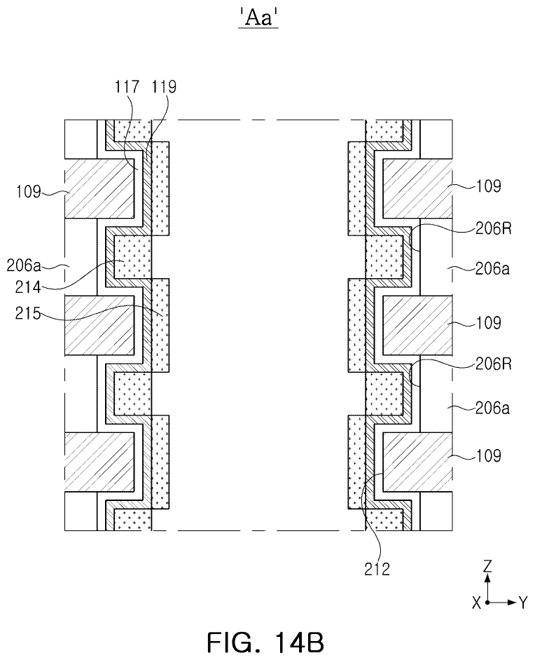

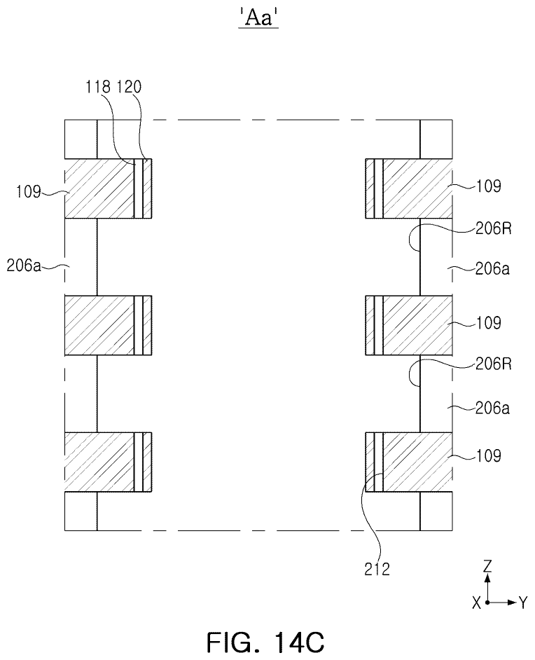

Referring to FIGS. 12 and 14A, at least one first liner layer covering the side surfaces of the sacrificial layers 109 and the first insulating portions 206a may be formed (S130). For example, the forming the at least one first liner layer may include forming a first material layer 117 and a second material layer 119 in order.

Referring to FIGS. 12 and 14B, first mask layers 214 may be formed on the at least one liner layer 217 and 219 in the recess regions 206R (S135). Second mask layers 215 may be formed on the at least one first liner layer 117 and 119 not covered by the first mask layers 214 (S140). For example, the first mask layers 214 may be formed of silicon oxide, and the second mask layers 215 may be formed of polysilicon formed on the second material layer 119 of the at least one first liner layer 217 or 219 not covered by the first mask layers 214.

Referring to FIGS. 12 and 14C, at least one liner pattern 118 and 120 disposed on the same or substantially the same level as a level of the sacrificial layers 109 may be formed by removing the at least one liner layer 117 and 119 and the first mask layer 214 from the recess regions 206R (S145). In an example, the at least one liner pattern 118 or 120 may be the first insulating layer (118 in FIG. 4B) and the first data storage layer (120 in FIG. 4B) described above.

Thereafter, the second mask layers 215 may be removed.

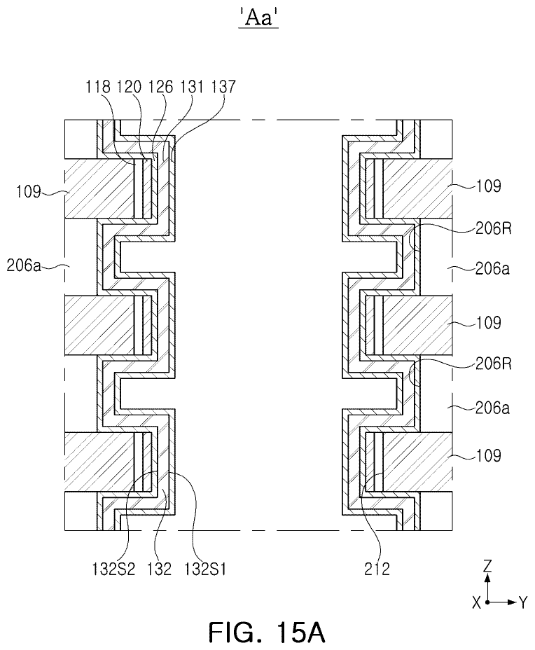

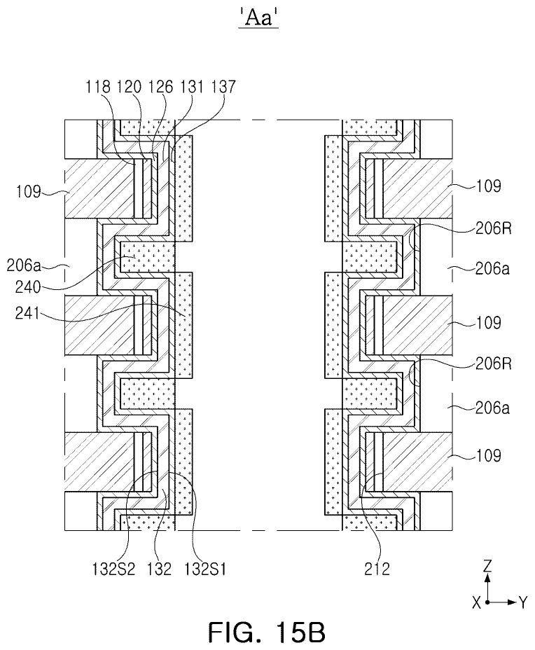

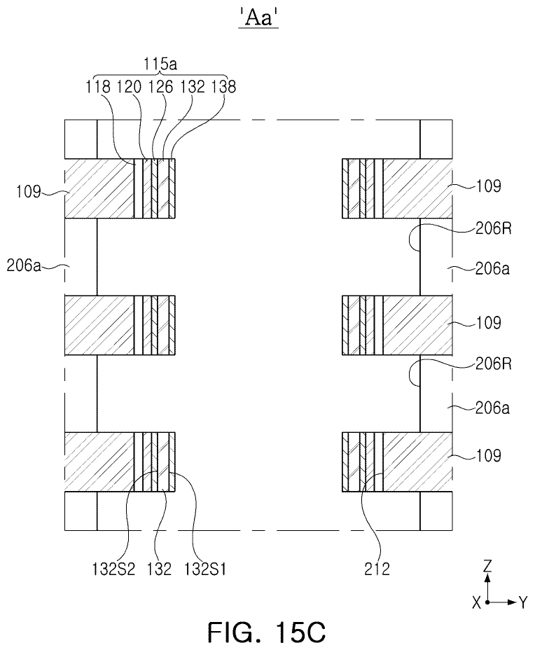

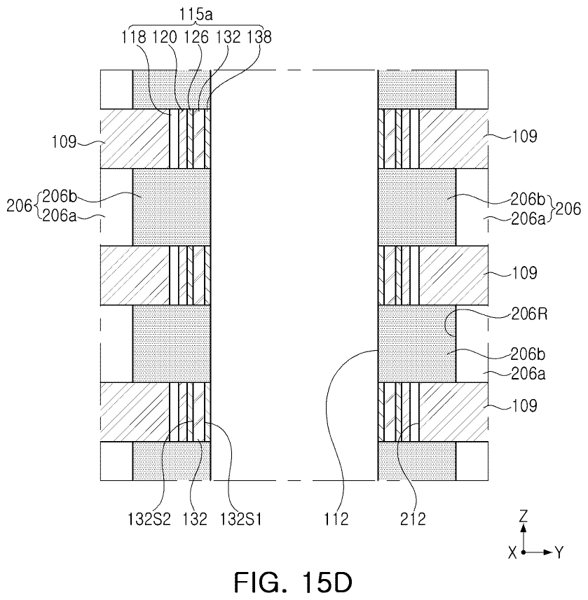

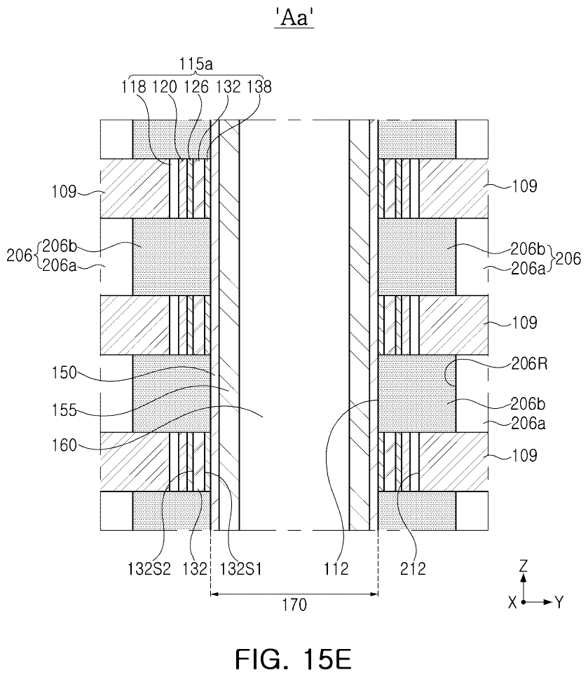

Referring to FIG. 15A, at least one second liner layer covering the recess regions 206R and the at least one liner pattern 118 and 120 may be formed. The forming the at least one second liner layer may include forming a third material layer 126, a fourth material layer 131, and a fifth material layer 137 in order.

Referring to FIG. 15B, third mask layers 240 may be formed on the at least one second liner layer 126, 131, and 137 in the recess regions 206R. Fourth mask layers 241 may be formed on at least one second liner layer 126, 131, and 137 not covered by the third mask layers 240. For example, the third mask layers 240 may be formed of silicon oxide, and the fourth mask layers 241 may be formed of polysilicon formed on the fifth material layer 137 of the at least one second liner layer 126, 131, and 137 not covered by the third mask layers 240.

Referring to FIG. 15C, by removing the at least one second liner layer 126, 131, 137 and the third mask layer 340 in the recess regions 206R, at least one second liner pattern 126, 132, and 138 disposed on the same or substantially the same level as a level of the sacrificial layers 109 may be formed. In an example, the at least one second liner pattern 126, 132, and 138 may be the second conductive layer 126, the second data storage layer 132, and the first conductive layer 138 described above. Accordingly, the first insulating layer (118 in FIG. 4B), the first data storage layer (120 in FIG. 4B), the second conductive layer 126, the second data storage layer 132 and the first conductive layer 138 may be included in the protruding portions 115a as in FIG. 4B. Using the method in FIGS. 13B to 15C, the protrusions 115a may be configured to have various shapes as in the example embodiments described above.

Referring to FIGS. 12 and 15D, second insulating portions 206b may be formed in the recess regions 206R (S150). The first and second insulating portions 206a and 206b may form interlayer insulating layers 206. Accordingly, a hole 112 defined along the side surfaces of the interlayer insulating layers 2016 may be formed. Thereafter, the fourth mask layers 341 may be removed.

Referring to FIG. 15e, a vertical pillar 170 may be formed in the hole 112 (S160). The vertical pillar 170 may be formed in the same manner as in FIG. 11C. Thereafter, the process may be the same or substantially the same as in the aforementioned example of the method of manufacturing a semiconductor.

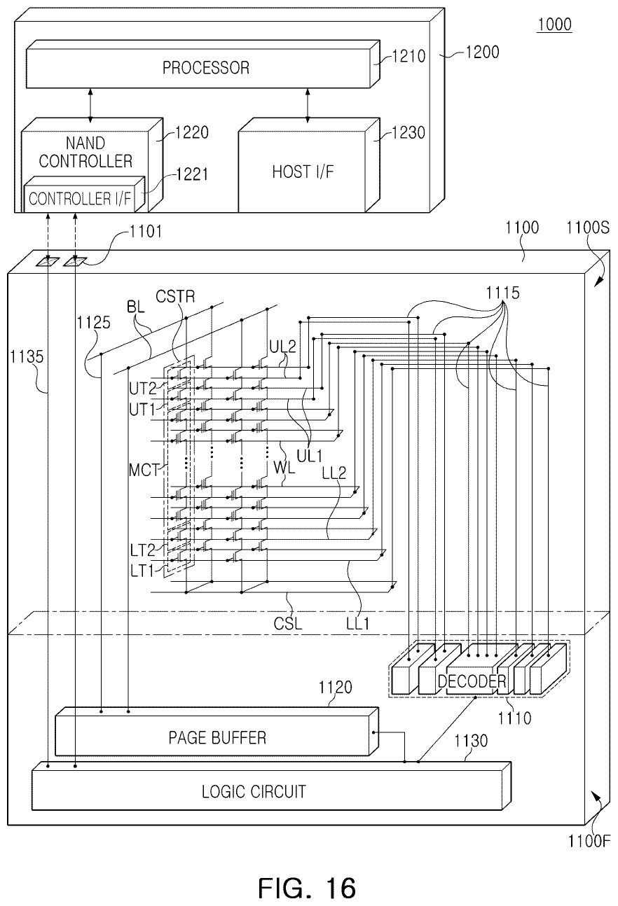

In the description below, a data storage system including a semiconductor device according to an example embodiment will be described with reference to FIGS. 16, 17, and 20.

FIG. 16 is a diagram illustrating a data storage system including a semiconductor device according to an example embodiment.

Referring to FIG. 16, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

In an example embodiment, the data storage system 1000 may be configured as an electronic system that stores data.

The semiconductor device 1100 may be implemented as a non-volatile memory device. The semiconductor device 1100 may be configured as a semiconductor device according to one of the example embodiments described above with reference to FIGS. 1 to 9. The semiconductor device 1100 may include a first structure 1100F and a second structure 1100S on the first structure 1100F.

The first structure 1100F may be implemented as a peripheral circuit structure including a decoder circuit 1110, a page buffer 1120, and a logic circuit 1130. For example, the first structure 1100F may include the peripheral circuit structure (LC in FIG. 2A and LCa in FIG. 9) described above. The peripheral circuit (21 in FIG. 2A or 311 in FIG. 6) may be configured as a transistor including a decoder circuit 1110, a page buffer 1120, and a logic circuit 1130.

The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

The source structures 18, 21, and 24 described above may include a silicon layer with N-type conductivity, and at least a portion of the source structures 18, 21, and 24 may form the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

As described in FIG. 2B, the plurality of memory cell transistors MCTs may include the intermediate gate electrodes 185M, which may be wordlines, the channel layer 155 of the vertical structure VS, and the protrusions 1015.

In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

The gate electrodes (FIG. 2B, 185) described above may form the gate lower lines LL1 and LL2, the wordlines WL and the gate upper lines UL1 and UL2.

The common source line CSL, the first and second gate lower lines LL1, LL2, wordlines WL, and the first and second gate upper lines UL1 and UL2 may be electrically connected to the decoder circuit 1110 through the first connection wires 1115 extending from the first structure 1100F to the second structure 1100S.

The bitlines BL may be electrically connected to the page buffer 1120 through second connection wires 1125 extending from the first structure 1100F to the second structure 1100S. The bitlines BL may be the bitlines (87 in FIG. 2A) described above.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130.

The semiconductor device 1000 may further include an input/output pad 1101. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S. Accordingly, the controller 1200 may be electrically connected to the semiconductor device 1000 through the input/output pad 1101 and may control the semiconductor device 1000.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

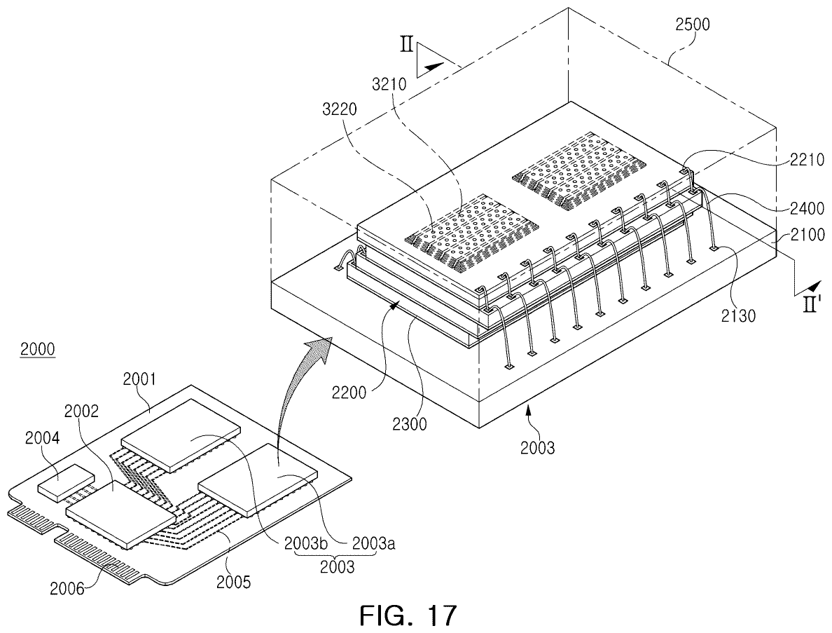

FIG. 17 is a perspective diagram illustrating a data storage system including a semiconductor device according to an example embodiment.

Referring to FIG. 17 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the semiconductor chips 2200 may include a semiconductor device according to of the example embodiments described above with reference to FIGS. 1 to 9.

Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210.

In the example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

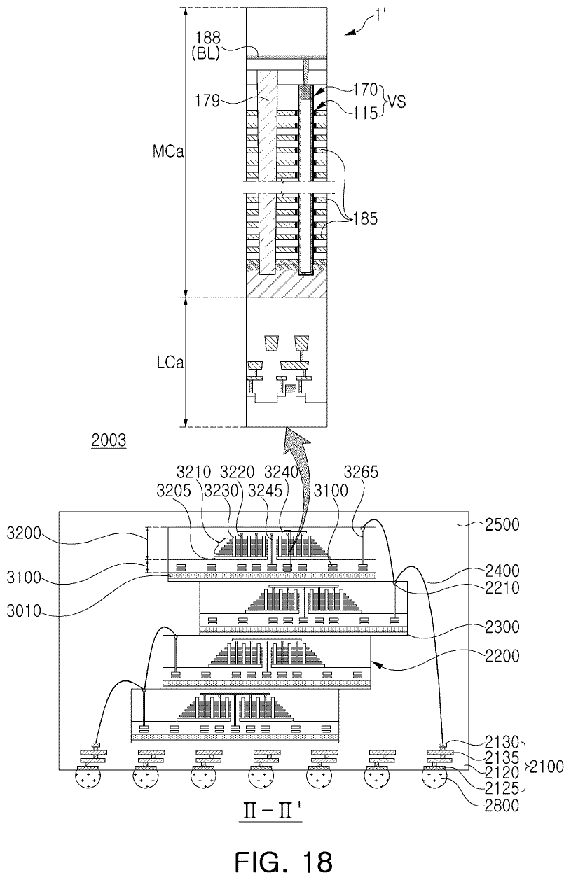

FIG. 18 is a cross-sectional diagram illustrating a semiconductor package according to an example embodiment, illustrating an example embodiment of the semiconductor package 2003 in FIG. 17 taken along line II-II′.

Referring to FIG. 18, in the semiconductor package 2003, the package substrate 2100 may be implemented as a printed circuit substrate. The package substrate 2100 may include may include a package substrate body portion 2120, package upper pads 2130 disposed on an upper surface of the package substrate body portion 2120 (see FIG. 15), lower pads 2125 disposed on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main the substrate 2001 of the data storage system 2000 through the conductive connection portions 2800.

Each of the semiconductor chips 2200 may include a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 penetrating through the gate stack structure 3210, bitlines 3240 electrically connected to the channel structures 3220, and contact plugs 3235 electrically connected to the wordlines WL of the gate stack structure 3210. The first structure 3100 may include the first structure 1100F in FIG. 16, and the second structure 3200 may include the second structure 1100S in FIG. 16.

Each of the semiconductor chips 2200 may include a through-interconnection 3245 electrically connected to the peripheral interconnections 3110 of the first structure 3100 and extending into the second structure 3200. The through-wiring 3245 may penetrate through the stack structure 3210 and may be further disposed on the outside of the stack structure 3210.

Each of the semiconductor chips 2200 may further include an input/output connection line 3265 electrically connected to the peripheral wires 3110 of the first structure 3100 and extending into the second structure 3200, and input/output pad 2210 electrically connected to the input/output connection line 3265.

In FIG. 18, the enlarged portion indicated by reference numeral “1” may indicate that the semiconductor chips 2200 in FIG. 18 may be modified to include the same cross-sectional structure as in FIG. 9. Accordingly, each of the semiconductor chips 2200 may include a semiconductor device 1 according to one of the example embodiments described above with reference to FIGS. 1 to 8, instead of the semiconductor device 1′ according to the example embodiment in FIG. 9.

According to the aforementioned example embodiments, a semiconductor device which may include a first data storage layer and a second data storage layer formed of different materials may be provided. Since the semiconductor device may include the first data storage layer for storing data using a charge trap and the second data storage layer for storing data using a polarization state, the memory window of the semiconductor device may be increased, and endurance and retention properties of the semiconductor device may be improved.

Also, a vertical structure including a vertical pillar and protrusions disposed between the vertical pillar and the gate electrodes and spaced apart from each other in the vertical direction may be provided. The vertical structure may include the first and second data storage layers, and each of the protrusions may include a conductive layer in contact with the second data storage layer. The free charges of the conductive layer may compensate for the polarization charges of the second data storage layer, which may be formed of a ferroelectric material. Accordingly, since the conductive layers in contact with the second data storage layer may reduce depolarization of the second data storage layer, the memory window may be limited and/or prevented from being reduced due to depolarization of the second data storage layer.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a stack structure including interlayer insulating layers and gate electrodes alternately stacked in a vertical direction;
a vertical pillar in a hole penetrating through the stack structure, the vertical pillar including a channel layer; and
protrusions between the vertical pillar and the gate electrodes, the protrusions spaced apart from each other in the vertical direction, wherein
each of the protrusions include a first data storage layer, a second data storage layer between the first data storage layer and the channel layer, and a first conductive layer,
the second data storage layer includes a first side surface and a second side surface opposing each other, and
the first conductive layer is in contact with the first side surface of the second data storage layer, and
a material of the second data storage layer is different from a material of the first data storage layer.

2. The semiconductor device of claim 1,
wherein the first data storage layer includes a charge trap layer, and
wherein the second data storage layer includes a ferroelectric layer.

3. The semiconductor device of claim 1, wherein a thickness of the second data storage layer is greater than a thickness of the first data storage layer in a horizontal direction perpendicular to the vertical direction.

4. The semiconductor device of claim 1, wherein
each of the protrusions further includes a second conductive layer spaced apart from the first conductive layer, and
the second conductive layer is in contact with the second side surface of the second data storage layer.

5. The semiconductor device of claim 1, wherein
each of the protrusions further includes a first insulating layer in contact with the first data storage layer, and
the first insulating layer is between the first data storage layer and the second data storage layer.

6. The semiconductor device of claim 1,
wherein each of the protrusions further includes an insulating layer in contact with the first data storage layer, and
wherein the first data storage layer is between the insulating layer and the second data storage layer.

7. The semiconductor device of claim 1, wherein each of the protrusions further includes an interfacial insulating layer between the second data storage layer and the channel layer.

8. The semiconductor device of claim 1, wherein the vertical pillar further includes an interfacial insulating layer covering an external side surface of the channel layer.

9. The semiconductor device of claim 1,
wherein the vertical pillar further includes an insulating core region and a pad pattern on the insulating core region,
wherein a portion of the channel layer is on a side surface of the insulating core region, and
wherein the pad pattern is connected to the channel layer.

10. The semiconductor device of claim 1, further comprising:
a peripheral circuit structure vertically overlapping the stack structure.

11. The semiconductor device of claim 1,
wherein each of the interlayer insulating layers includes a first insulating portion and a second insulating portion such that the interlayer insulating layers provide a plurality of first insulating portions and a plurality of second insulating portions,
wherein the plurality of second insulating portions are between the plurality of first insulating portions and the vertical pillar, and
wherein the protrusions vertically overlap the plurality of second insulating portions, respectively.

12. A semiconductor device, comprising:
a stack structure including interlayer insulating layers and gate electrodes alternately stacked in a vertical direction; and
a vertical structure penetrating through the stack structure, the vertical structure including a vertical pillar disposed in a hole penetrating through the stack structure, the vertical structure including protrusions between the vertical pillar and the gate electrodes, and the vertical pillar including a channel layer,
wherein the protrusions are spaced apart from each other in the vertical direction,
wherein the vertical structure includes a first data storage layer and a second data storage layer,
wherein each of the protrusions includes at least one of the first data storage layer and the second data storage layer,
wherein each of the protrusions further includes a first conductive layer in contact with at least one of the first data storage layer and the second data storage layer, and
a material of the second data storage layer is different from a material of the first data storage layer.

13. The semiconductor device of claim 12,
wherein the first data storage layer includes a charge trap layer, and
wherein the second data storage layer includes a ferroelectric layer.

14. The semiconductor device of claim 13,
wherein each of the protrusions includes the first data storage layer, the second data storage layer, and the first conductive layer,
wherein the second data storage layer is between the first data storage layer and the channel layer, and
wherein the first conductive layer is in contact with the second data storage layer.

15. The semiconductor device of claim 14,
wherein each of the protrusions further includes a second conductive layer in contact with the second data storage layer,
wherein the second conductive layer is spaced apart from the first conductive layer, and
wherein the second data storage layer is between the first conductive layer and the second conductive layer.

16. The semiconductor device of claim 12,
wherein each of the protrusions includes the first data storage layer and the first conductive layer,
wherein the vertical pillar includes the second data storage layer, and
wherein the second data storage layer is in contact with the first conductive layer.

17. The semiconductor device of claim 12, wherein
each of the interlayer insulating layers includes a first insulating portion and a second insulating portion,
the second insulating portion is between the first insulating portion and the vertical pillar, and
the protrusions vertically overlap the second insulating portions.

18. A data storage system, comprising:
a semiconductor device including an input/output pad; and
a controller electrically connected to the semiconductor device through the input/output pad and configured to control the semiconductor device, wherein
the semiconductor device further includes a stack structure and a vertical structure penetrating through the stack structure,
the stack structure includes interlayer insulating layers and gate electrodes alternately stacked in a vertical direction,
the vertical structure includes a vertical pillar in a hole penetrating through the stack structure,
the vertical pillar includes a channel layer,
the vertical pillar further includes protrusions between the vertical pillar and the gate electrodes,
the protrusions are spaced apart from each other in the vertical direction,
the vertical structure includes a first data storage layer and a second data storage layer,
each of the protrusions includes at least one of the first data storage layer and the second data storage layer,
each of the protrusions further includes a first conductive layer in contact with at least one of the first data storage layer and the second data storage layer, and
a material of the second data storage layer is different from a material of the first data storage layer.

19. The semiconductor device of claim 18,
wherein the first data storage layer includes a charge trap layer,
wherein the second data storage layer includes a ferroelectric layer,
wherein each of the protrusions includes the first data storage layer, the second data storage layer, and the first conductive layer,
wherein the second data storage layer is between the first data storage layer and the channel layer,
wherein the first conductive layer is in contact with the second data storage layer,
wherein each of the protrusions further includes a second conductive layer in contact with the second data storage layer,
wherein the second conductive layer is spaced apart from the first conductive layer, and
wherein the second data storage layer is between the first conductive layer and the second conductive layer.

20. The semiconductor device of claim 18,
wherein each of the interlayer insulating layers includes a first insulating portion and a second insulating portion,
the second insulating portion is between the first insulating portion and the vertical pillar, and
wherein the protrusions vertically overlap the second insulating portions.
